(19) United States
(12) Patent Application Publication
(10) Pub. No.: US 2022/0393433 A1
(43) Pub. Date: Dec. 8, 2022

(54) SURFACE EMISSION LASER, SURFACE EMISSION LASER ARRAY, ELECTRONIC EQUIPMENT, AND SURFACE EMISSION LASER MANUFACTURING METHOD

(71) Applicant: Sony Semiconductor Solutions Corporation, Kanagawa (JP)

(72) Inventor: Yoshihiko TAKAHASHI, Kumamoto (JP)

(21) Appl. No.: 17/773,312

(22) PCT Filed: Nov. 12, 2020
(86) PCT No.: PCT/JP2020/042261

§ 371 Date: Apr. 29, 2022

(30) Foreign Application Priority Data
Dec. 11, 2019 (JP) 2019-223552

(51) Int. Cl. H01S 5/18; H01S 5/42; H01S 5/227; H01S 5/343; H01S 5/042

(52) U.S. Cl. CPC H01S 5/18; H01S 5/42; H01S 5/2275; H01S 5/343; H01S 5/04256

(57) ABSTRACT

There are provided a surface emission laser 10, a surface emission laser array in which the surface emission laser 10 is arrayed two-dimensionally, and a surface emission laser manufacturing method that enable efficient injection of a current to an active layer 200b, while suppressing deterioration of the crystallinity of layers stacked above a contact area.

The present technology provides a surface emission laser 10 including a substrate 100, and a mesa structure 200 formed on the substrate 100, in which the mesa structure 200 includes at least a part of a first multilayer film reflector 200a stacked on the substrate 100, an active layer 200b stacked on the first multilayer film reflector 200a, and a second multilayer film reflector 200c stacked on the active layer 200b, and an impurity area 800 is provided over a contact area CA that is adjacent to the mesa structure 200, and contacts an electrode 600, and a side wall section of a portion of the mesa structure 200 which portion includes the first multilayer film reflector 200a.

### TECHNICAL FIELD

The technology according to the present disclosure (also called the “present technology” below) relates to a surface emission laser, a surface emission laser array, electronic equipment, and a surface emission laser manufacturing method.

### BACKGROUND ART

In the past, surface emission lasers having a substrate and a mesa structure formed on the substrate have been known.

For example, PTL 1 discloses a surface emission laser in which a contact area which is adjacent to a mesa structure and contacts an electrode is doped with impurities at a high concentration.

### CITATION LIST

### Patent Literature

### [PTL1]

JP-H10-223975-A

### SUMMARY

### Technical Problem

However, it has not been possible with the surface emission laser disclosed in PTL 1 to inject a current to an active layer efficiently while suppressing deterioration of the crystallinity of layers stacked at a position above the contact area (a position farther from the substrate than the contact area is).

In view of this, an object of the present technology is to provide a surface emission laser, a surface emission laser array in which the surface emission laser is arrayed two-dimensionally, and a surface emission laser manufacturing method that enable efficient injection of a current to an active layer, while suppressing deterioration of the crystallinity of layers stacked above a contact area.

### Solution to Problem

The present technology provides a surface emission laser including a substrate, and a mesa structure formed on the substrate, in which the mesa structure includes at least a part of a first multilayer film reflector stacked on the substrate, an active layer stacked on the first multilayer film reflector, and a second multilayer film reflector stacked on the active layer, and an impurity area is provided over a contact area that is adjacent to the mesa structure and contacts an electrode, and over a side wall section of a portion of the mesa structure that the portion includes the first multilayer film reflector.

The impurity area may be continuous from the contact area to the side wall section.

The mesa structure may include the whole of the first multilayer film reflector, and the contact area may include a part of the substrate.

The mesa structure may include a portion other than a bottom section of the first multilayer film reflector, and the contact area may include a part of the bottom section of the first multilayer film reflector.

The mesa structure may include the whole of the first multilayer film reflector, the surface emission laser may further include a contact layer arranged between the substrate and the first multilayer film reflector, and the contact area may include a part of the contact layer.

The contact area may include a part of the substrate.

A thickness of the contact layer may be equal to or smaller than 1 μm.

An impurity concentration of the impurity area may be lower than 5×10¹⁹ cm⁻³.

Another electrode may contact a surface of the mesa structure that the surface is located on a same side where the electrode is arranged corresponding to the contact area.

The substrate may be a semi-insulating substrate or a low-doped substrate.

The surface emission laser may emit light toward a side of the substrate that the side is opposite to a mesa-structure side.

In the surface emission laser, an AlGaAs-based compound semiconductor or a GaN-based compound semiconductor may be used.

The surface emission laser may further include a current constriction layer arranged between the first multilayer film reflector and the second multilayer film reflector.

At least one of the first and second multilayer film reflectors may be a semiconductor multilayer film reflector.

At least one of the first and second multilayer film reflectors may be a dielectric multilayer film reflector.

The present technology also provides a surface emission laser array, in which the surface emission laser is arrayed two-dimensionally.

The present technology also provides electronic equipment including the surface emission laser array.

The present technology also provides a surface emission laser manufacturing method including a step of stacking at least a first multilayer film reflector, an active layer, and a second multilayer film reflector on a substrate in this order, and producing a stacked layer body, a step of etching the stacked layer body until a part of a side surface of at least the first multilayer film reflector is exposed, and forming a first mesa structure, a step of forming an insulating film in the first mesa structure and an area adjacent to the first mesa structure, a step of removing the insulating film formed in the adjacent area, a step of diffusing impurities from the adjacent area to a side wall section of a portion of the first mesa structure that the portion includes the first multilayer film reflector, a step of further etching the stacked layer body until another section of the side surface of at least the first multilayer film reflector is exposed, and forming and producing a second mesa structure to replace the first mesa structure, and a step of providing an electrode on an area adjacent to the second mesa structure.

At the step of producing the stacked layer body, a contact layer may be stacked on the substrate before the first multilayer film reflector is stacked on the substrate, and at the step of forming the second mesa structure, the stacked layer body in which the first mesa structure is formed may be etched until at least the contact layer is exposed.

The present technology provides a surface emission laser manufacturing method including a step of stacking at least a first multilayer film reflector, an active layer, and a second multilayer film reflector on a substrate in this order, and producing a stacked layer body, a step of etching the stacked layer body until at least a part of a side surface of at least the first multilayer film reflector is exposed, and forming a mesa structure, a step of forming an insulating film in the mesa structure and an area adjacent to the mesa structure, a step of removing the insulating film formed in the adjacent area, a step of diffusing impurities from the adjacent area to a side wall section of a portion of the mesa structure that the portion includes the first multilayer film reflector, and a step of providing an electrode on the adjacent area.

At the step of producing the stacked layer body, a contact layer may be stacked on the substrate before the first multilayer film reflector is stacked on the substrate, and at the step of forming the mesa structure, the stacked layer body may be etched until at least the contact layer is exposed.

### BRIEF DESCRIPTION OF DRAWINGS

FIG. 1 is a cross-sectional view depicting a configuration example of a surface emission laser according to a first embodiment of the present technology.

FIG. 2 is the first half of a flowchart for explaining a first example of a surface emission laser manufacturing method according to the first embodiment of the present technology.

FIG. 3 is the second half of the flowchart for explaining the first example of the surface emission laser manufacturing method according to the first embodiment of the present technology.

FIG. 4 is a cross-sectional view (No. 1) of a step of the first example of the surface emission laser manufacturing method according to the first embodiment of the present technology.

FIG. 5 is a cross-sectional view (No. 2) of a step of the first example of the surface emission laser manufacturing method according to the first embodiment of the present technology.

FIG. 6 is a cross-sectional view (No. 3) of a step of the first example of the surface emission laser manufacturing method according to the first embodiment of the present technology.

FIG. 7 is a cross-sectional view (No. 4) of a step of the first example of the surface emission laser manufacturing method according to the first embodiment of the present technology.

FIG. 8 is a cross-sectional view (No. 5) of a step of the first example of the surface emission laser manufacturing method according to the first embodiment of the present technology.

FIG. 9 is a cross-sectional view (No. 6) of a step of the first example of the surface emission laser manufacturing method according to the first embodiment of the present technology.

FIG. 10 is a cross-sectional view (No. 7) of a step of the first example of the surface emission laser manufacturing method according to the first embodiment of the present technology.

FIG. 11 is a cross-sectional view (No. 8) of a step of the first example of the surface emission laser manufacturing method according to the first embodiment of the present technology.

FIG. 12 is a cross-sectional view (No. 9) of a step of the first example of the surface emission laser manufacturing method according to the first embodiment of the present technology.

FIG. 13 is a cross-sectional view (No. 10) of a step of the first example of the surface emission laser manufacturing method according to the first embodiment of the present technology.

FIG. 14 is a cross-sectional view (No. 11) of a step of the first example of the surface emission laser manufacturing method according to the first embodiment of the present technology.

FIG. 15 is a cross-sectional view (No. 12) of a step of the first example of the surface emission laser manufacturing method according to the first embodiment of the present technology.

FIG. 16 is a cross-sectional view (No. 13) of a step of the first example of the surface emission laser manufacturing method according to the first embodiment of the present technology.

FIG. 17 is a cross-sectional view (No. 14) of a step of the first example of the surface emission laser manufacturing method according to the first embodiment of the present technology.

FIG. 18 is a cross-sectional view (No. 15) of a step of the first example of the surface emission laser manufacturing method according to the first embodiment of the present technology.

FIG. 19 is a cross-sectional view (No. 16) of a step of the first example of the surface emission laser manufacturing method according to the first embodiment of the present technology.

FIG. 20 is a cross-sectional view (No. 17) of a step of the first example of the surface emission laser manufacturing method according to the first embodiment of the present technology.

FIG. 21 is a cross-sectional view (No. 18) of a step of the first example of the surface emission laser manufacturing method according to the first embodiment of the present technology.

FIG. 22 is a cross-sectional view (No. 19) of a step of the first example of the surface emission laser manufacturing method according to the first embodiment of the present technology.

FIG. 23 is a cross-sectional view (No. 20) of a step of the first example of the surface emission laser manufacturing method according to the first embodiment of the present technology.

FIG. 24 is a cross-sectional view (No. 21) of a step of the first example of the surface emission laser manufacturing method according to the first embodiment of the present technology.

FIG. 25 is the first half of a flowchart for explaining a second example of the surface emission laser manufacturing method according to the first embodiment of the present technology.

FIG. 26 is the second half of a flowchart for explaining the second example of the surface emission laser manufacturing method according to the first embodiment of the present technology.

FIG. 27 is a cross-sectional view (No. 1) of a step of the second example of the surface emission laser manufacturing method according to the first embodiment of the present technology.

FIG. 28 is a cross-sectional view (No. 2) of a step of the second example of the surface emission laser manufacturing method according to the first embodiment of the present technology.

FIG. 29 is a cross-sectional view (No. 3) of a step of the second example of the surface emission laser manufacturing method according to the first embodiment of the present technology.

FIG. 30 is a cross-sectional view (No. 4) of a step of the second example of the surface emission laser manufacturing method according to the first embodiment of the present technology.

FIG. 31 is a cross-sectional view (No. 5) of a step of the second example of the surface emission laser manufacturing method according to the first embodiment of the present technology.

FIG. 32 is a cross-sectional view (No. 6) of a step of the second example of the surface emission laser manufacturing method according to the first embodiment of the present technology.

FIG. 33 is a cross-sectional view (No. 7) of a step of the second example of the surface emission laser manufacturing method according to the first embodiment of the present technology.

FIG. 34 is a cross-sectional view (No. 8) of a step of the second example of the surface emission laser manufacturing method according to the first embodiment of the present technology.

FIG. 35 is a cross-sectional view (No. 9) of a step of the second example of the surface emission laser manufacturing method according to the first embodiment of the present technology.

FIG. 36 is a cross-sectional view (No. 10) of a step of the second example of the surface emission laser manufacturing method according to the first embodiment of the present technology.

FIG. 37 is a cross-sectional view (No. 11) of a step of the second example of the surface emission laser manufacturing method according to the first embodiment of the present technology.

FIG. 38 is a cross-sectional view (No. 12) of a step of the second example of the surface emission laser manufacturing method according to the first embodiment of the present technology.

FIG. 39 is a cross-sectional view (No. 13) of a step of the second example of the surface emission laser manufacturing method according to the first embodiment of the present technology.

FIG. 40 is a cross-sectional view (No. 14) of a step of the second example of the surface emission laser manufacturing method according to the first embodiment of the present technology.

FIG. 41 is a cross-sectional view (No. 15) of a step of the second example of the surface emission laser manufacturing method according to the first embodiment of the present technology.

FIG. 42 is a cross-sectional view (No. 16) of a step of the second example of the surface emission laser manufacturing method according to the first embodiment of the present technology.

FIG. 43 is a cross-sectional view (No. 17) of a step of the second example of the surface emission laser manufacturing method according to the first embodiment of the present technology.

FIG. 44 is a cross-sectional view (No. 18) of a step of the second example of the surface emission laser manufacturing method according to the first embodiment of the present technology.

FIG. 45 is a cross-sectional view depicting a configuration example of a surface emission laser according to a second embodiment of the present technology.

FIG. 46 is a cross-sectional view depicting a configuration example of a surface emission laser according to a third embodiment of the present technology.

FIG. 47 is a cross-sectional view depicting a configuration example of a surface emission laser according to a first modification example of the first embodiment of the present technology.

FIG. 48 is a cross-sectional view depicting a configuration example of a surface emission laser according to a second modification example of the first embodiment of the present technology.

FIG. 49 is a cross-sectional view depicting a configuration example of a surface emission laser according to a third modification example of the first embodiment of the present technology.

### DESCRIPTION OF EMBODIMENTS

Suitable embodiments of the present technology are explained in detail below with reference to the attached figures. Note that overlapping explanations of constituent elements having substantially identical functional configuration are omitted by giving the constituent elements identical reference signs in the present specification and figures. Embodiments explained below are depicted as representative embodiments of the present technology and do not limit the interpretation of the scope of the present technology. In the present specification, even in a case where it is described that a plurality of advantages is attained with each of a surface emission laser, a surface emission laser array, electronic equipment, and a surface emission laser manufacturing method according to the present technology, it is sufficient if at least one advantage is attained with each of the surface emission laser, the surface emission laser array, the electronic equipment, and the surface emission laser manufacturing method according to the present technology. Advantages described in the present specification are described merely for illustrative purposes, advantages of the present technology are not limited to them and also there may be other advantages.

In addition, explanations are given in the following order.

1. Surface emission laser according to first embodiment of present technology

(1) Configuration of surface emission laser according to first embodiment of present technology

(2) First example of surface emission laser manufacturing method according to first embodiment of present technology

(3) Second example of surface emission laser manufacturing method according to first embodiment of present technology

(4) Effects of surface emission laser according to first embodiment of present technology

(5) Advantages of surface emission laser according to first embodiment of present technology

2. Surface emission laser according to second embodiment of present technology

3. Surface emission laser according to third embodiment of present technology

4. Modification examples of surface emission laser according to present technology

5. Use examples of surface emission laser to which present technology is applied

### Examples of Application to Electronic Equipment

1. <Surface Emission Laser According to First Embodiment of Present Technology>

(1) Configuration of Surface Emission Laser

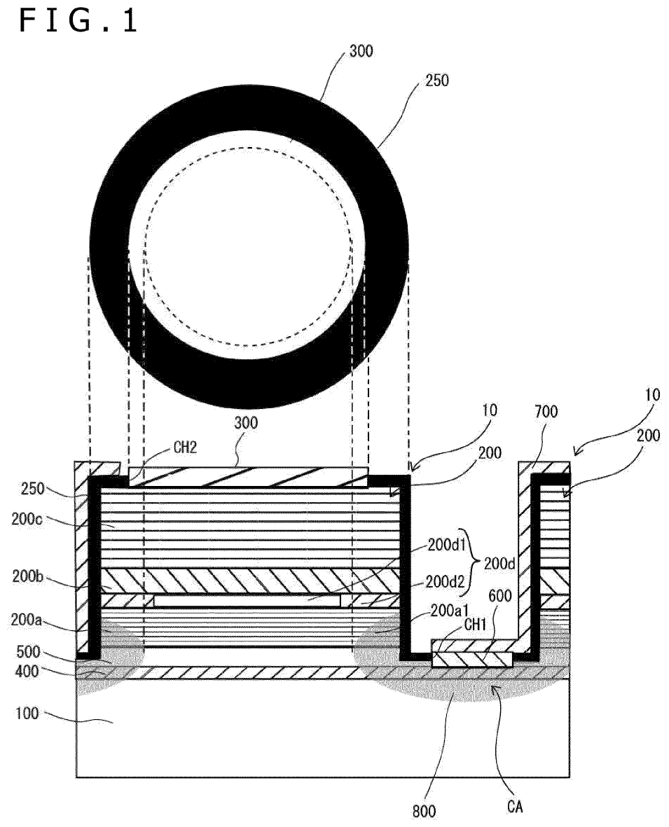

FIG. 1 is a cross-sectional view depicting a configuration example of a surface emission laser 10 according to a first embodiment of the present technology. In the explanation below, an upward direction and a downward direction in cross-sectional views such as FIG. 1 are the upward direction and the downward direction, respectively, for convenience.

As depicted in FIG. 1, the surface emission laser 10 includes a substrate 100 and a mesa structure 200 formed on the substrate 100. Note that the upper view in FIG. 1 is a plan view of an area corresponding to the mesa structure 200 of the surface emission laser 10.

In the case explained as an example below, a plurality of two-dimensionally arrayed surface emission lasers 10 is included in a surface emission laser array.

In this case, the plurality of surface emission lasers 10 shares at least the substrate 100, and a plurality of mesa structures 200 is arrayed two-dimensionally on the common substrate 100.

As an example, the surface emission laser 10 emits light toward a side of the substrate 100 which side is opposite to the mesa-structure-200 side. That is, as an example, the surface emission laser 10 is a backside-emission surface emission laser that emits laser light toward the backside (lower-surface side) of the substrate 100.

As an example, the substrate 100 is a first-conductivity-type (e.g. p-type) GaAs substrate.

Here, preferably, the substrate 100 is a substrate with low optical absorbance (a substrate that can suppress deterioration of optical output power), for example, a semi-insulating substrate or a low-doped substrate (a substrate with a low impurity concentration) because the substrate 100 is positioned on the emission side of the mesa structure 200 included in a laser resonator as mentioned later.

A semi-insulating substrate is a substrate including, as a material, a compound semiconductor such as gallium arsenide or indium phosphide, but not including (not doped with) impurities, and is a substrate that exhibits a high resistance (specific resistance: several MΩ/□). Because a semi-insulating substrate not only has a high electron mobility, but also exhibits a high resistance, it can also reduce leakage current and earth capacity.

In view of this, preferably, as the substrate 100, for example, among first-conductivity-type GaAs substrates, in particular, a semi-insulating semi-insulating substrate or a low-doped substrate is used.

The mesa structure 200 includes a first multilayer film reflector 200a stacked on the substrate 100, an active layer 200b stacked on the first multilayer film reflector 200a, and a second multilayer film reflector 200c stacked on the active layer 200b.

The laser resonator includes the first multilayer film reflector 200a, the active layer 200b, and the second multilayer film reflector 200c.

For example, the mesa structure 200 has an substantially columnar shape but may have another pillar shape such as an substantially elliptic columnar shape or a polygonal pillar shape, for example.

As an example, the first and second multilayer film reflectors 200a and 200c are both semiconductor multilayer reflectors. Multilayer film reflectors are also called distributed Bragg reflectors. Semiconductor multilayer film reflectors which are one type of multilayer film reflector (distributed Bragg reflector) have low optical absorbance, high reflectance, and electrical conductivity.

As an example, the first multilayer film reflector 200a is a first-conductivity-type (e.g. p-type) semiconductor multilayer film reflector, and has a structure in which multiple types (e.g. two types) of semiconductor layer having mutually different refractive indices are stacked alternately with an optical thickness which is the ¼ wavelength of an oscillation wavelength. Each refractive index layer of the first multilayer film reflector 200a includes a first-conductivity-type (e.g. p-type) AlGaAs-based compound semiconductor.

For example, the active layer 200b has a quantum well structure including a barrier layer and a quantum well layer including an AlGaAs-based compound semiconductor. The quantum well structure may be a single quantum well structure (QW structure) or may be a multiple quantum well structure (MQW structure).

As an example, the second multilayer film reflector 200c is a second-conductivity-type (e.g. n-type) semiconductor multilayer film reflector, and has a structure in which multiple types (e.g. two types) of semiconductor layer having mutually different refractive indices are stacked alternately with an optical thickness which is the ¼ wavelength of an oscillation wavelength. Each refractive index layer of the second multilayer film reflector 200c includes a second-conductivity-type (e.g. n-type) AlGaAs-based compound semiconductor.

Furthermore, the mesa structure 200 includes a current constriction layer 200d arranged between the first multilayer film reflector 200a and the active layer 200b.

As an example, the current constriction layer 200d has a first-conductivity-type (e.g. n-type) non-oxidized area 200d1 including AlAs, and an oxidized area 200d2 including an AlAs oxide (e.g. Al₂O₃) surrounding the non-oxidized area 200d1.

The mesa structure 200 and an area adjacent to the mesa structure 200 (an area between adjacent mesa structures 200) are, except for a part of them, covered with a series of insulating films 250. For example, the insulating film 250 includes SiO₂, SiN, SiON, or the like.

At an insulating film 250 at a top section (more specifically, the top surface of the second multilayer film reflector 200c) of the mesa structure 200, a contact hole CH2 is formed, and a cathode electrode 300 is provided in the contact hole CH2 such that the cathode electrode 300 contacts the top section of the mesa structure 200.

The cathode electrode 300 may have a single layer structure or may have a stacked layer structure.

For example, the cathode electrode 300 includes at least one type of metal (including alloy) selected from a group including Au, Ag, Pd, Pt, Ni, Ti, V, W, Cr, Al, Cu, Zn, Sn, and In.

In a case where the cathode electrode 300 has a stacked layer structure, for example, the cathode electrode 300 includes a material such as Ti/Au, Ti/Al, Ti/Al/Au, Ti/Pt/Au, Ni/Au, Ni/Au/Pt, Ni/Pt, Pd/Pt, or Ag/Pd.

Furthermore, as an example, the mesa structure 200 includes a contact layer 400 including a GaAs-based material arranged between the substrate 100 and the first multilayer film reflector 200a. The contact layer 400 is shared by the plurality of surface emission lasers 10.

The contact layer 400 is positioned on the emission side of the mesa structure 200 included in the laser resonator. Because of this, a thickness of the contact layer 400 is preferably equal to or smaller than 1 μm and is more preferably equal to or smaller than 500 nm. If the thickness of the contact layer 400 is equal to or smaller than 1 μm, optical absorption at the contact layer 400 can be reduced, and this in turn can suppress deterioration of the optical output power.

Furthermore, as an example, the mesa structure 200 has an etching stop layer 500 arranged between the contact layer 400 and the first multilayer film reflector 200a. The etching stop layer 500 is shared by the plurality of surface emission lasers 10.

A top section of the etching stop layer 500 is included in a bottom section of the mesa structure 200.

An area between adjacent mesa structures 200 (a portion adjacent to the mesa structures 200) on the substrate 100 includes a bottom surface of a contact hole CH1 which is an area not covered with the insulating film 250, and includes a contact area CA contacting an anode electrode 600.

The contact area CA includes a part of the substrate 100 and a part of the contact layer 400.

For example, the anode electrode 600 is provided on the contact area CA, that is, in the contact hole CH1, such that the anode electrode 600 contacts the contact layer 400.

The anode electrode 600 is connected with an electrode pad (not depicted) arranged around the surface emission laser array by a metal wire 700 formed by patterning along the plurality of mesa structures 200.

The anode electrode 600 may have a single layer structure or may have a stacked layer structure.

For example, the anode electrode 600 includes at least one type of metal (including alloy) selected from a group including Au, Ag, Pd, Pt, Ni, Ti, V, W, Cr, Al, Cu, Zn, Sn, and In.

In a case where the anode electrode 600 has a stacked layer structure, for example, the anode electrode 600 includes a material such as Ti/Au, Ti/Al, Ti/Al/Au, Ti/Pt/Au, Ni/Au, Ni/Au/Pt, Ni/Pt, Pd/Pt, or Ag/Pd.

The cathode electrode 300 contacts a surface of the mesa structure 200 which surface is located on the same side where the anode electrode 600 is arranged corresponding to the contact area CA.

An impurity area 800 (a portion colored grey in FIG. 1) is provided over the contact area CA and a side wall section 200a1 of a portion of the mesa structure 200 which portion includes the first multilayer film reflector 200a. In the present specification, an “impurity area” means an area (high concentration impurity area) where the impurity concentration is higher than other areas (at least a surrounding area).

Explaining in detail, the impurity area 800 includes the contact area CA, the side wall section 200a1, and the area between the contact area CA and the side wall section 200a1.

The impurity area 800 is continuous from the contact area CA to the side wall section 200a1. That is, the impurity area 800 includes a current path from the anode electrode 600 to the first multilayer film reflector 200a.

As an example, the impurity area 800 is formed continuously over the entire area of the mesa structure 200 in the circumferential direction. Note that the impurity area 800 may have discontinuous portions (interrupted portions) at parts of the mesa structure 200 in the circumferential direction.

As depicted in FIG. 1, preferably, the side wall section 200a1 is an outer portion of an area (an area corresponding to the non-oxidized area 200d1 of the current constriction layer 200d) forming an optical waveguide of a portion of the mesa structure 200 which portion includes the first multilayer film reflector 200a.

For example, the impurity area 800 includes a metal such as Zn or ions such as beryllium ions.

The impurity area 800 is continuous from the contact area CA to the side wall section 200a1. Note that the impurity area 800 may have discontinuous portions (interrupted portions) between the contact area CA and the side wall section 200a1.

The impurity concentration of the impurity area 800 is preferably lower than 5×10¹⁹ cm⁻³, and is more preferably lower than 5×10¹⁸ cm⁻³.

The impurity concentration of the impurity area 800 is preferably almost uniform over the entire area of the impurity area 800 but may have slight variations.

(2) First Example of Surface Emission Laser Manufacturing Method According to First Embodiment of Present Technology

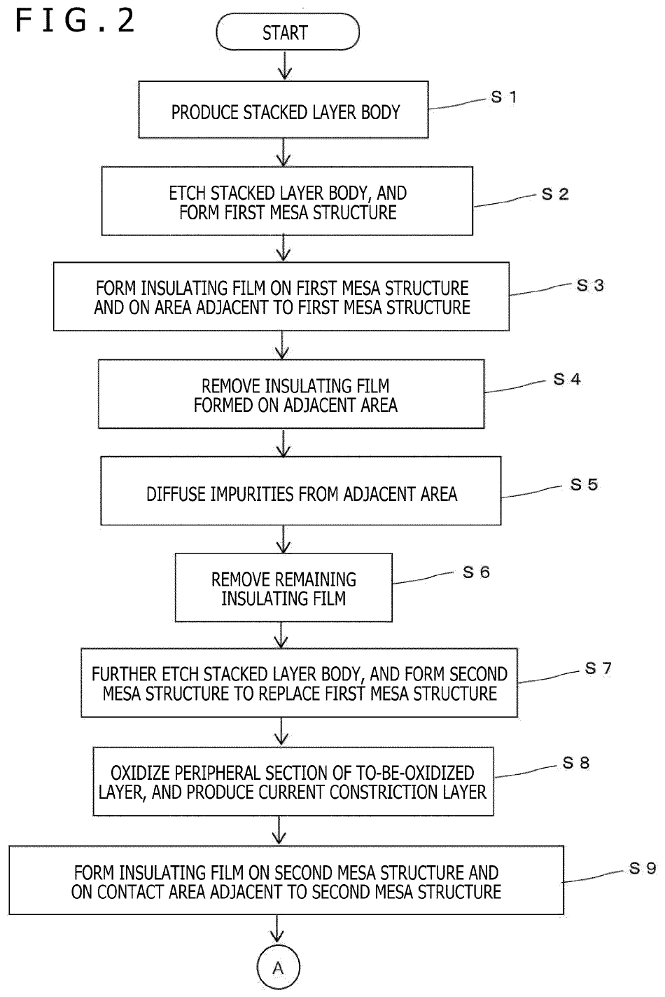

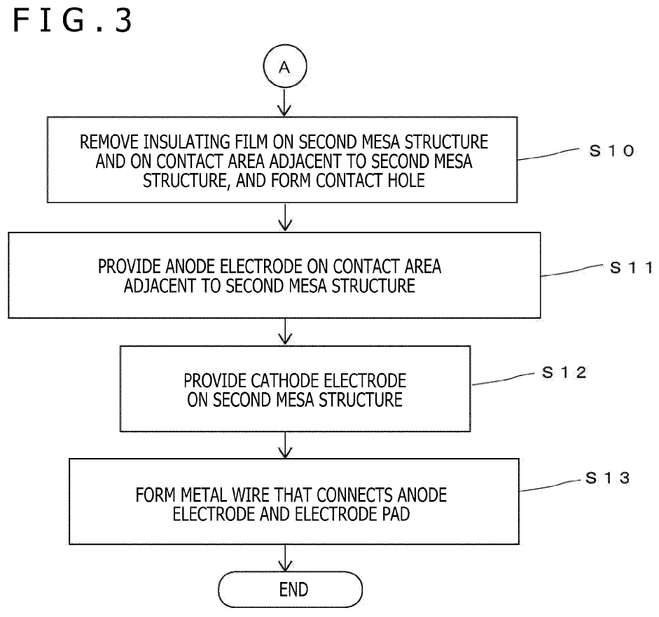

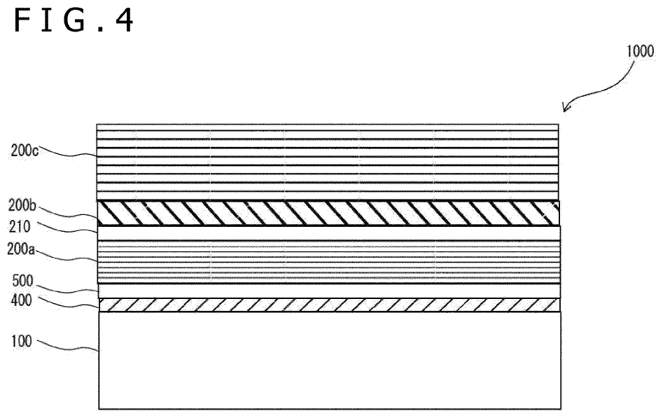

A first example of a method of manufacturing the surface emission laser 10 is explained below with reference to FIG. 2 to FIG. 24. FIG. 2 and FIG. 3 are flowcharts for explaining the first example of the method of manufacturing the surface emission laser 10. FIG. 4 to FIG. 24 are each a cross-sectional view (step cross-sectional view) of a step of the first example of the method of manufacturing the surface emission laser 10. Here, as an example, a plurality of surface emission laser arrays is produced simultaneously on one wafer which is a base material of the substrate 100 by a semiconductor manufacturing method (at this time, a plurality of surface emission lasers 10 of each surface emission laser array is also produced simultaneously). Next, the series of the plurality of integrated surface emission laser arrays are separated from each other, and the plurality of chip-shaped surface emission laser arrays (surface emission laser array chips) is obtained.

At the first Step S1, a stacked layer body 1000 is produced.

Specifically, by a chemical vapor deposition (CVD) method, for example, by a metal organic chemical vapor deposition (MOCVD) method, as depicted in FIG. 4, the contact layer 400, the etching stop layer 500, the first multilayer film reflector 200a, a to-be-selectively-oxidized layer 210, the active layer 200b, and the second multilayer film reflector 200c are stacked on the substrate 100 in this order sequentially.

At the next Step S2, the stacked layer body 1000 is etched (e.g. wet-etched), and a first mesa structure 150 is formed.

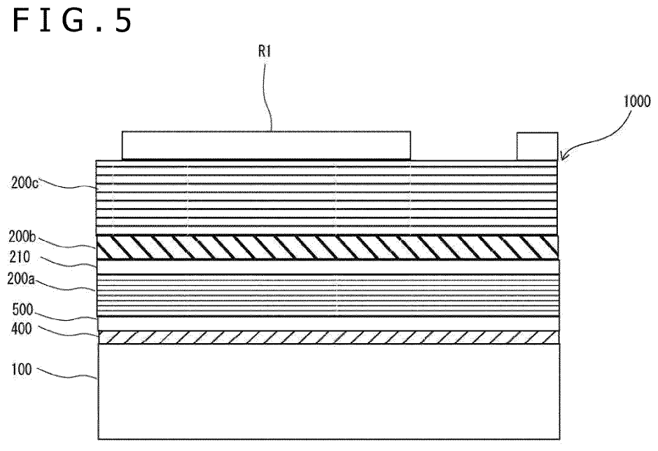

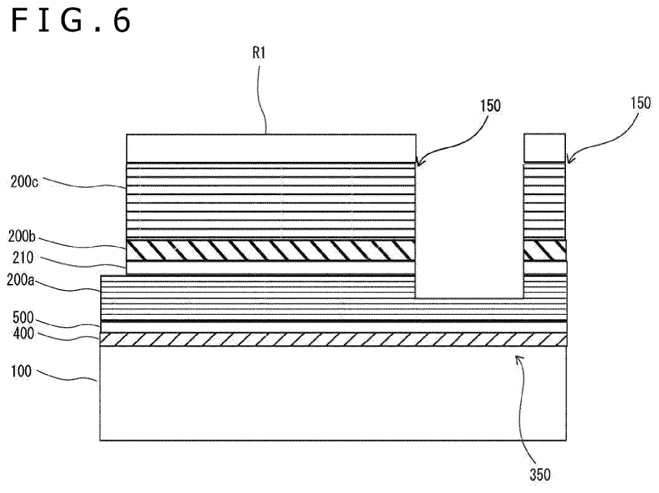

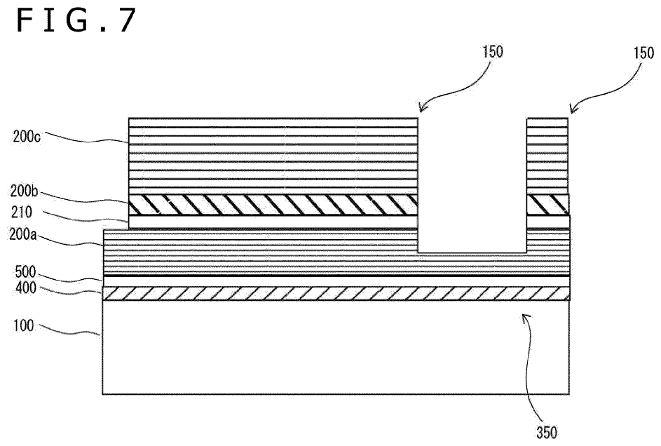

Specifically, as depicted in FIG. 5, a resist pattern R1 is formed by photolithography on the stacked layer body 1000 taken out from a deposition chamber. Next, as depicted in FIG. 6, using the resist pattern R1 as a mask, a part of the second multilayer film reflector 200c, active layer 200b, to-be-selectively-oxidized layer 210, and first multilayer film reflector 200a is selectively removed by using a sulfuric-acid-based etchant, for example. Thereby, the first mesa structure 150 is formed. The etching here is performed until the etching bottom surface reaches a position in the first multilayer film reflector 200a (to such a depth that the etching stop layer 500 is not exposed). Thereafter, as depicted in FIG. 7, the resist pattern R1 is removed.

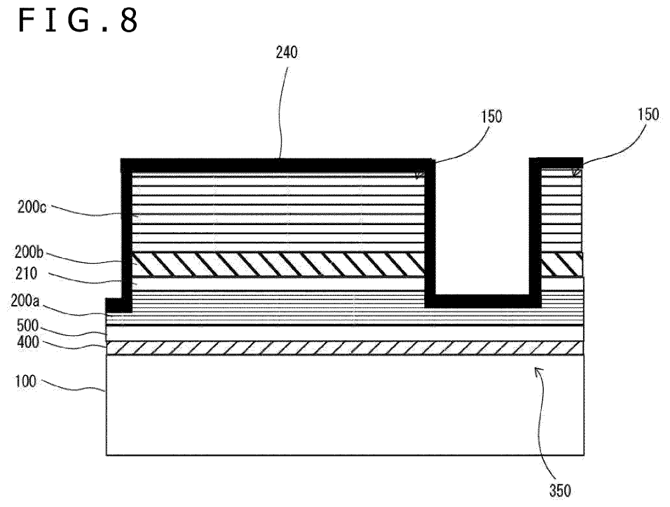

At the next Step S3, as depicted in FIG. 8, an insulating film 240 including, for example, SiO₂ is formed in the first mesa structure 150 and in an area 350 adjacent to the first mesa structure 150.

Specifically, the insulating film 240 is formed in the substantially entire area of the stacked layer body 1000 where the first mesa structure 150 is formed. The area 350 adjacent to the first mesa structure 150 is also called an “adjacent area 350” below. Here, the adjacent area 350 is located between two adjacent first mesa structures 150 in the plan view.

At the next Step S4, the insulating film 240 which is formed in the adjacent area 350 is removed.

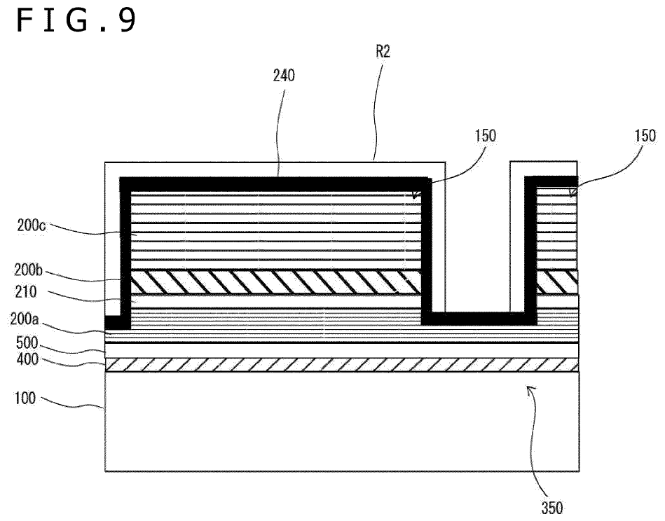

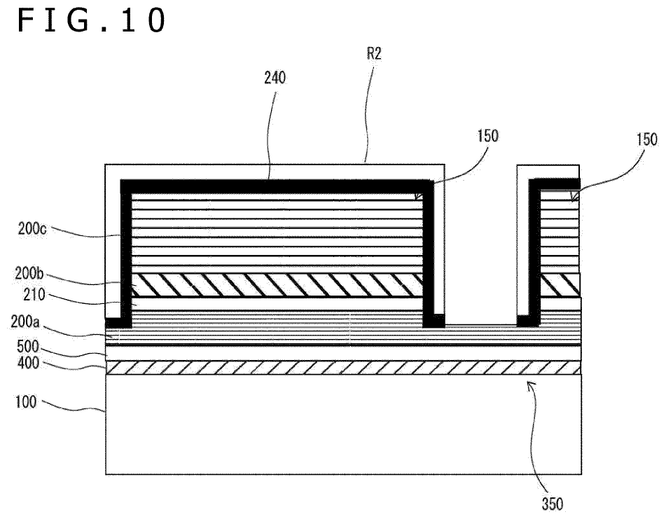

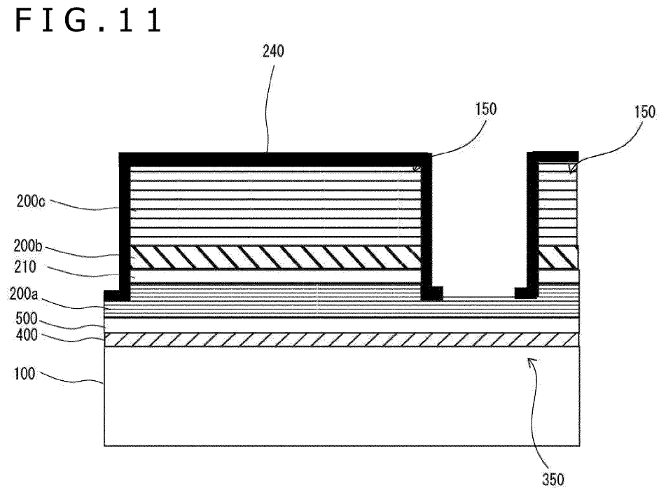

Specifically, as depicted in FIG. 9, a resist pattern R2 is formed by photolithography in an area other than the area 350 adjacent to the first mesa structure 150. Next, using the resist pattern R2 as a mask, as depicted in FIG. 10, the insulating film 240 which is formed in the adjacent area 350 is removed by etching by using a fluorinated-acid-based etchant, for example. Thereafter, as depicted in FIG. 11, the resist pattern R2 is removed.

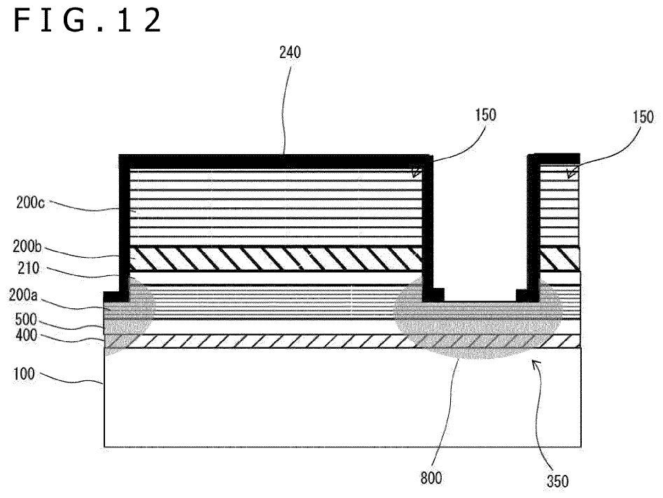

At the next Step S5, as depicted in FIG. 12, impurities are diffused from the area 350 adjacent to the first mesa structure 150, and the impurity area 800 is formed.

Specifically, impurities such as, for example, Zn are implanted and diffused from the adjacent area 350. For example, the impurity implantation rate and implantation time are adjusted such that the impurity area 800 is diffused to the first multilayer film reflector 200a, the etching stop layer 500, the contact layer 400, and the substrate 100. At this time, the insulating film 240 functions as a mask at time of the impurity diffusion. For example, if SiO₂ is used as a material of the insulating film 240, vacancy diffusion is generated from Ga at a SiO₂ interface due to diffusion, depressurization and heating, and it becomes easier to diffuse the impurities over a large area.

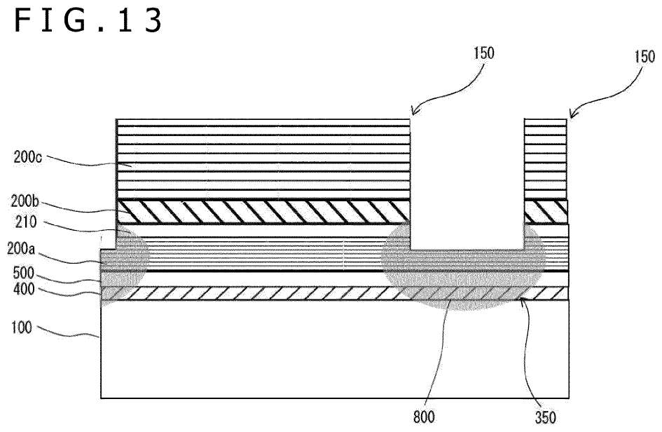

At the next Step S6, as depicted in FIG. 13, the remaining insulating film 240 is removed.

Specifically, the insulating film 240 which is formed in areas other than the adjacent area 350 is removed by using a fluorinated-acid-based etchant, for example.

At the next Step S7, the stacked layer body 1000 is etched (e.g. wet-etched) further, and the mesa structure 200 which is a second mesa structure to replace the first mesa structure 150 is formed.

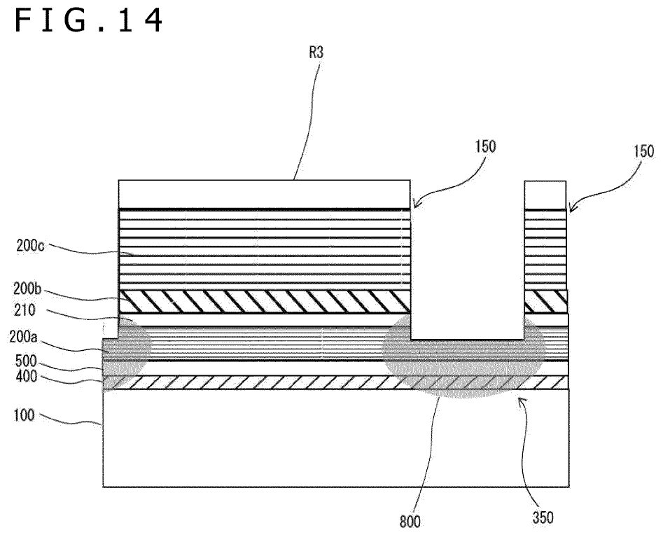

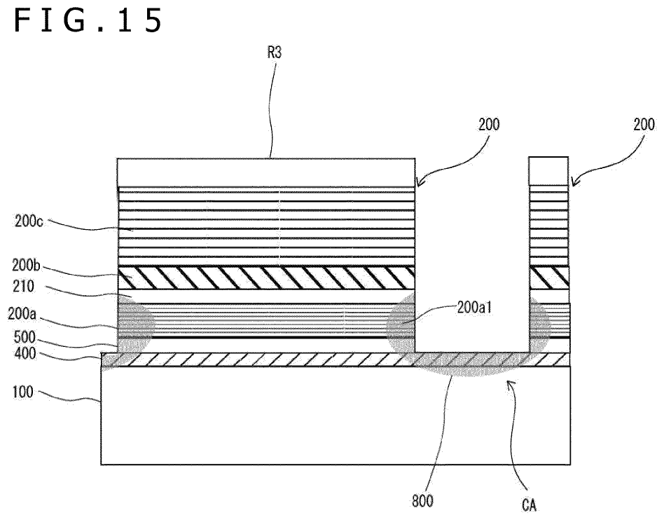

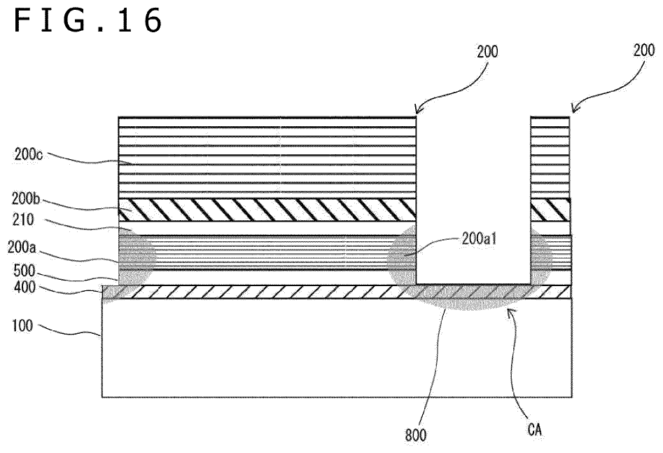

Specifically, as depicted in FIG. 14, a resist pattern R3 is formed by photolithography in the areas other than the adjacent area 350. Next, using the resist pattern R3 as a mask, as depicted in FIG. 15, the first multilayer film reflector 200a of the adjacent area 350 is removed selectively by using a sulfuric-acid-based etchant, for example. Thereby, the mesa structure 200 is formed. Thereafter, as depicted in FIG. 16, the resist pattern R3 is removed. The etching here is stopped when the etching stop layer 500 is removed, and the contact layer 400 is exposed. The mesa structure 200 is also called a “second mesa structure 200” below.

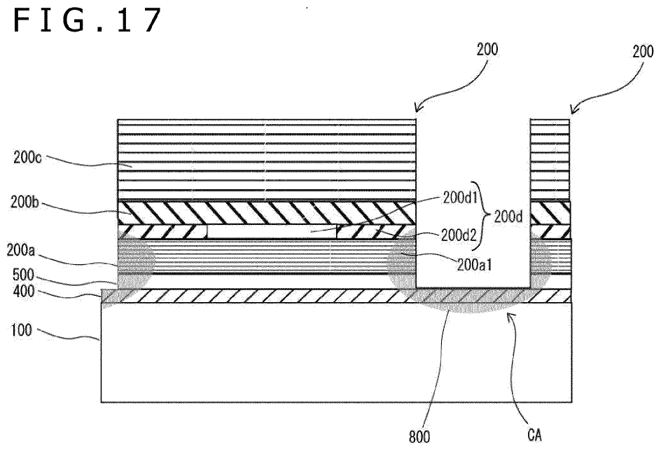

At the next Step S8, as depicted in FIG. 17, a peripheral section of the to-be-selectively-oxidized layer 210 (see FIG. 16) is oxidized, and the current constriction layer 200d is produced.

Specifically, the second mesa structure 200 is exposed to a water vapor atmosphere, the to-be-selectively-oxidized layer 210 is oxidized (selectively oxidized) from the side surface, and the current constriction layer 200d in which the periphery of the non-oxidized area 200d1 is surrounded by the oxidized area 200d2 is formed.

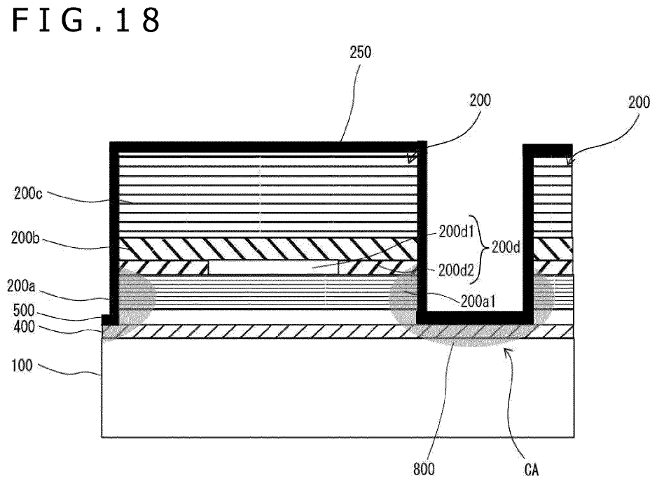

At the next Step S9, as depicted in FIG. 18, the insulating film 250 is formed on the second mesa structure 200 and on the contact area CA adjacent to the second mesa structure 200.

Specifically, the insulating film 250 is formed over the substantially entire area of the stacked layer body 1000. Here, the contact area CA is located between two adjacent second mesa structures 200 in the plan view.

At the next Step S10, the insulating film 250 which is located on the second mesa structure 200 and on the contact area CA adjacent to the second mesa structure 200 is removed, and a contact hole is formed.

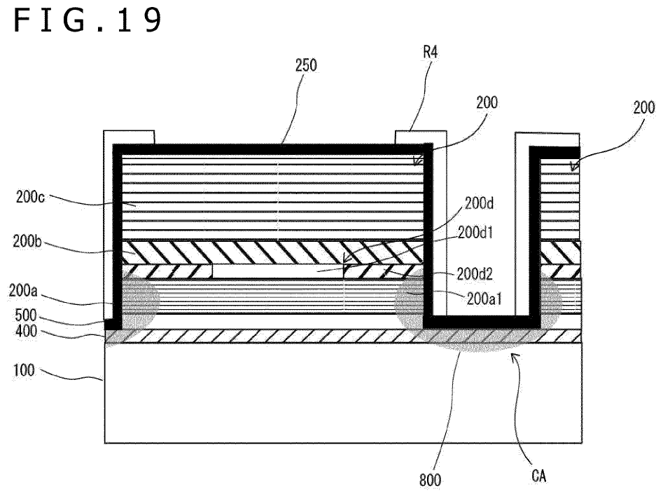

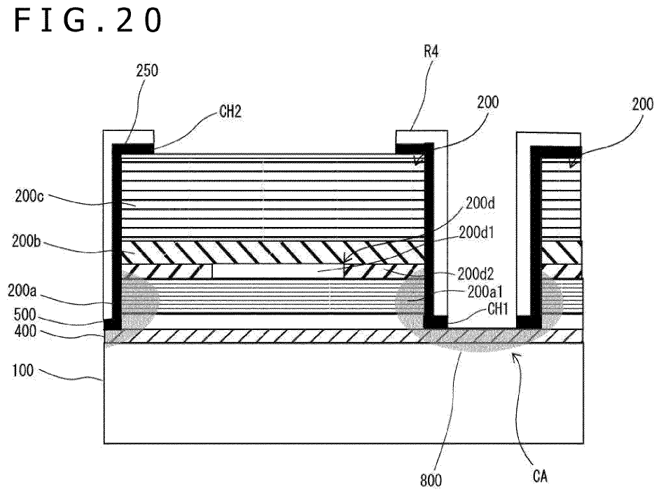

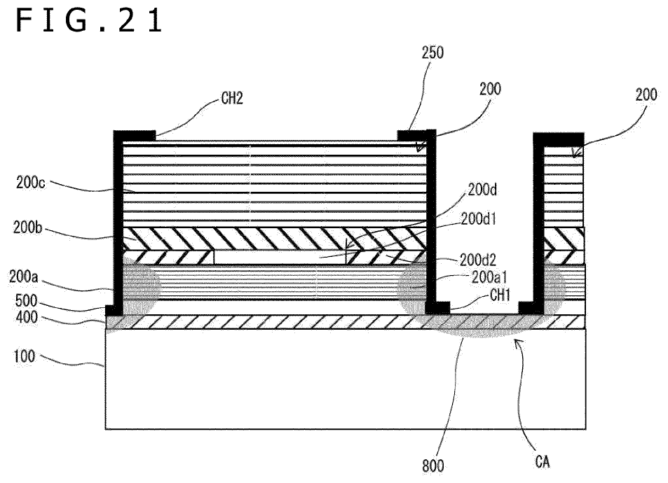

Specifically, as depicted in FIG. 19, a resist pattern R4 is formed by photolithography in areas other than the contact area CA adjacent to the second mesa structure 200 and a top section of the second mesa structure 200. Next, using the resist pattern R4 as a mask, as depicted in FIG. 20, the insulating film 250 which is located on the contact area CA and the insulating film 250 which is located on the top section of the second mesa structure 200 are removed by wet etching, and the contact holes CH1 and CH2 for electrode contact are formed. Thereafter, as depicted in FIG. 21, the resist pattern R4 is removed.

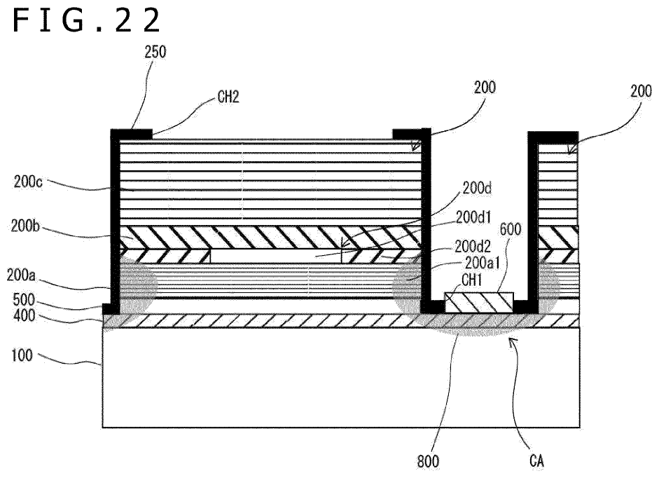

At the next Step S11, as depicted in FIG. 22, the anode electrode 600 is provided in the contact area CA adjacent to the second mesa structure 200.

Specifically, for example, by an EB vapor deposition method, for example, an Au/Ti film is formed in the contact area CA, the resist and for example Au/Ti on the resist are lifted off, and thereby the anode electrode 600 is formed in the contact hole CH1.

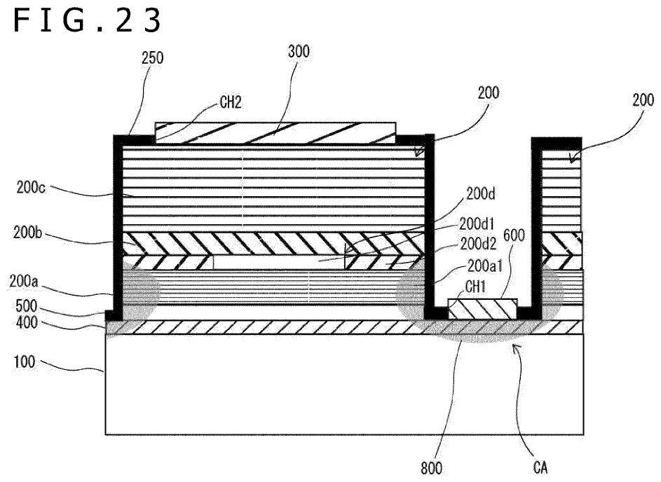

At the next Step S12, as depicted in FIG. 23, the cathode electrode 300 is provided on the top section of the second mesa structure 200.

Specifically, for example, by an EB vapor deposition method, an Au/Ti film is formed on the top section of the second mesa structure 200, the resist and Au/Ti on the resist are lifted off, and thereby the cathode electrode 300 is formed in the contact hole CH2 on the top section of the second mesa structure 200.

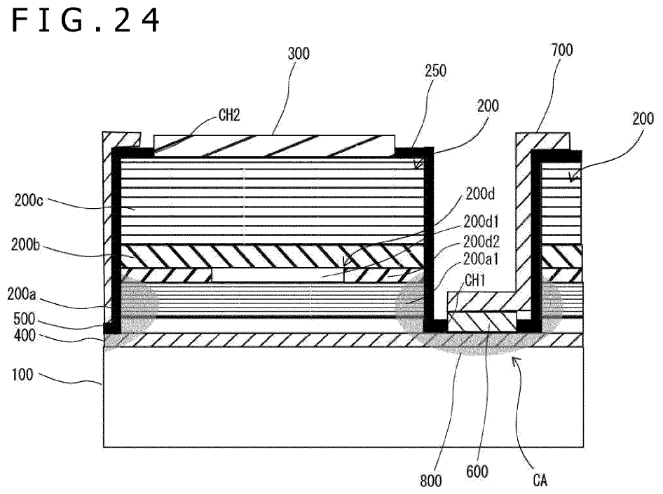

At the last Step S13, as depicted in FIG. 24, the metal wire 700 that connects the electrode pad and the anode electrode 600 provided in the contact area CA adjacent to the second mesa structure 200 is formed. Thereafter, processes such as annealing, film-thickness reduction by polishing the backside (the surface on a side opposite to the second-mesa-structure-200 side surface) of the wafer or formation of an anti-reflection coating on the backside of the wafer are performed, and a plurality of surface emission laser arrays on which a plurality of surface emission lasers 10 is arrayed two-dimensionally is formed on one wafer. Thereafter, the plurality of surface emission laser arrays is separated into a plurality of surface emission laser array chips by dicing.

Note that the order of Steps S11 and S12 described above may be reversed.

(2) Second Example of Surface Emission Laser Manufacturing Method According to First Embodiment of Present Technology

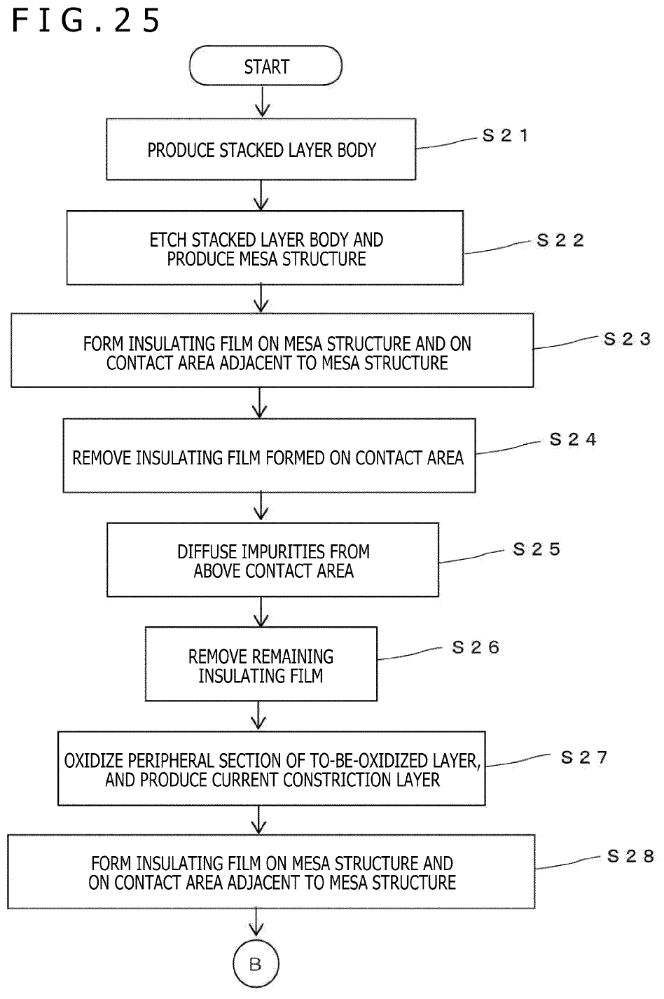

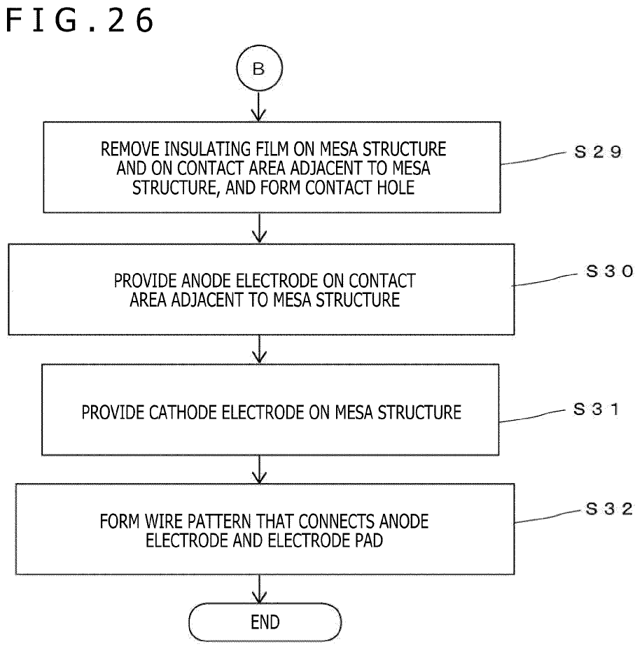

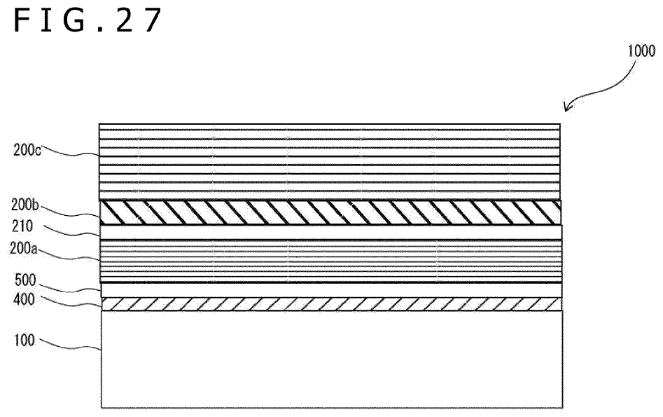

A second example of the method of manufacturing the surface emission laser 10 is explained below with reference to FIG. 25 to FIG. 44. FIG. 25 and FIG. 26 are flowcharts for explaining the second example of the method of manufacturing the surface emission laser 10. FIG. 27 to FIG. 44 are each a cross-sectional view (step cross-sectional view) of a step of the second example of the method of manufacturing the surface emission laser 10. Here, as an example, a plurality of surface emission laser arrays is produced simultaneously on one wafer which is a base material of the substrate 100 by a semiconductor manufacturing method (at this time, a plurality of surface emission lasers 10 of each surface emission laser array is also produced simultaneously). Next, the plurality of surface emission laser arrays is separated from each other, and the plurality of chip-shaped surface emission laser arrays (surface emission laser array chips) is produced.

At the first Step S21, the stacked layer body 1000 is produced.

Specifically, by a chemical vapor deposition (CVD) method, for example, by a metal organic chemical vapor deposition (MOCVD) method, as depicted in FIG. 27, the contact layer 400, the etching stop layer 500, the first multilayer film reflector 200a, the to-be-selectively-oxidized layer 210, the active layer 200b, and the second multilayer film reflector 200c are stacked on the substrate 100 in this order sequentially.

At the next Step S22, the stacked layer body 1000 is etched (e.g. wet-etched), and the mesa structure 200 is formed.

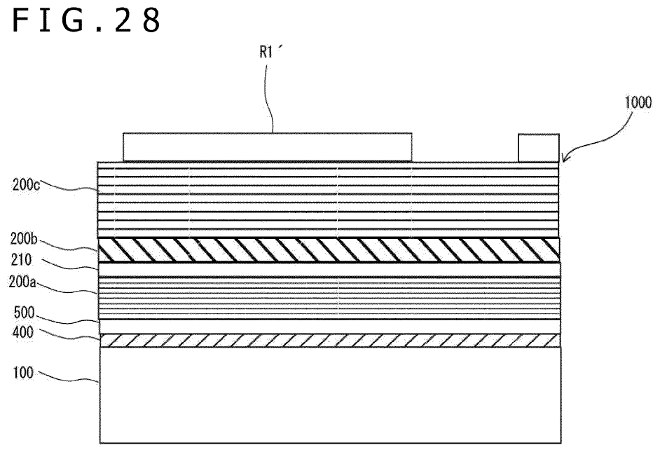

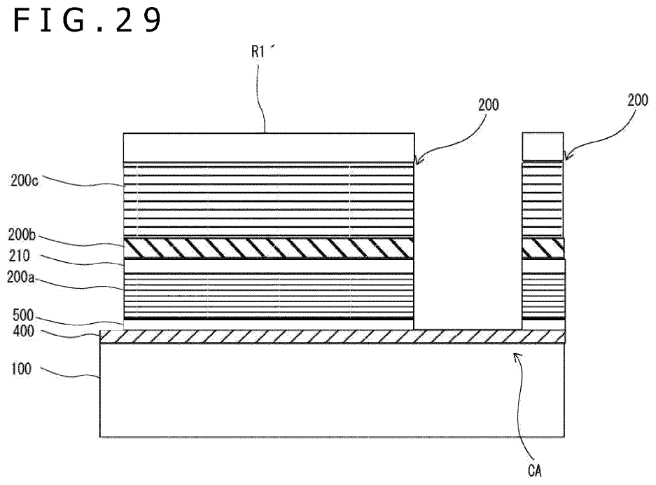

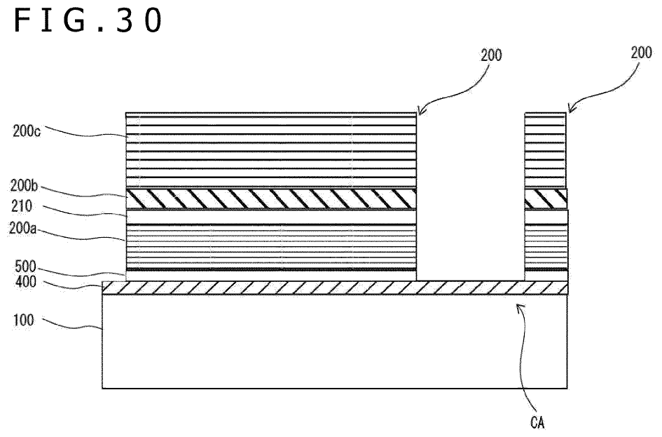

Specifically, as depicted in FIG. 28, a resist pattern R1′ is formed by photolithography on the stacked layer body 1000 taken out from a deposition chamber. Next, as depicted in FIG. 29, using the resist pattern R1′ as a mask, the second multilayer film reflector 200c, the active layer 200b, the to-be-selectively-oxidized layer 210, and the first multilayer film reflector 200a are selectively removed by using a sulfuric-acid-based etchant, for example. Thereby, the mesa structure 200 is formed. The etching here is stopped when the etching stop layer 500 is removed and the contact layer 400 is exposed. Thereafter, as depicted in FIG. 30, the resist pattern R1′ is removed.

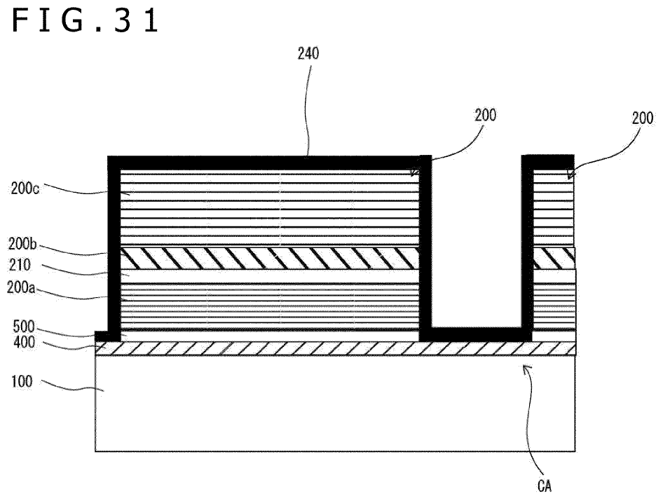

At the next Step S23, as depicted in FIG. 31, the insulating film 240 including, for example, SiO₂ is formed on the mesa structure 200 and on the contact area CA adjacent to the mesa structure 200. Specifically, the insulating film 240 is formed over the substantially entire area of the stacked layer body 1000. Here, the contact area CA is located between two adjacent mesa structures 200 in the plan view.

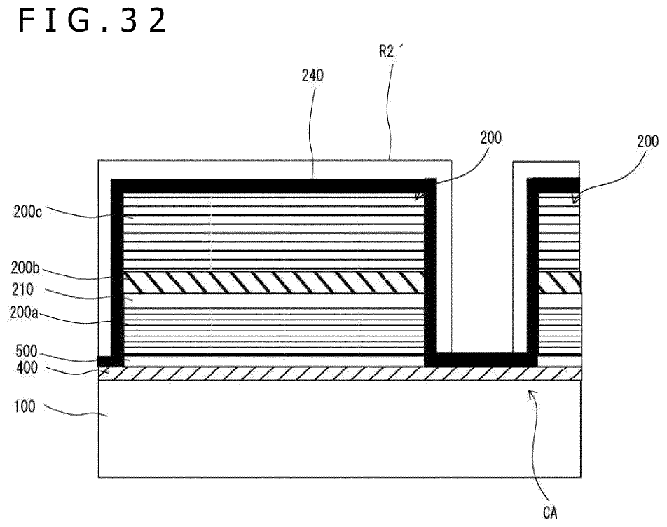

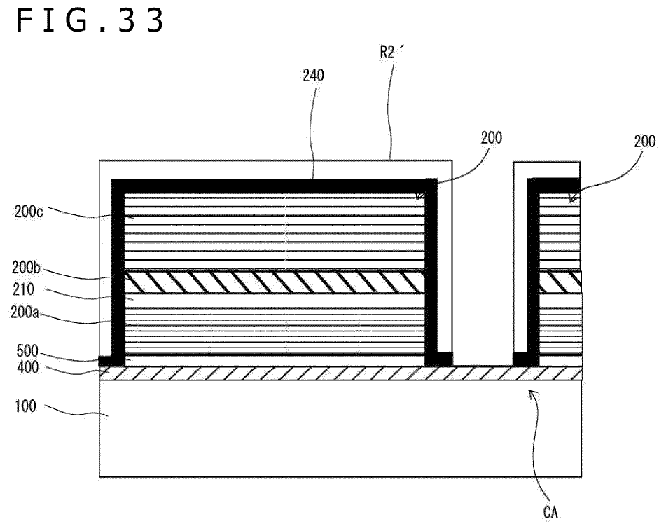

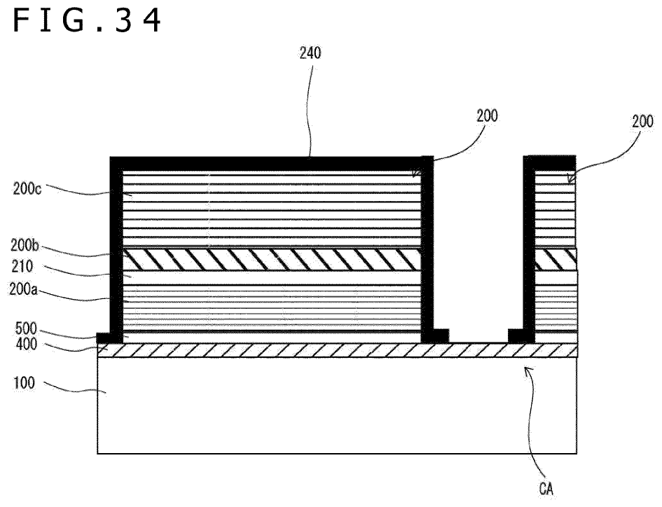

At the next Step S24, the insulating film 240 which is formed on the contact area CA is removed. Specifically, as depicted in FIG. 32, a resist pattern R2′ is formed by photolithography in an area other than the contact area CA adjacent to the mesa structure 200. Next, as depicted in FIG. 33, using the resist pattern R2′ as a mask, the insulating film 240 which is formed on the contact area CA is removed by wet etching. Thereafter, as depicted in FIG. 34, the resist pattern R2′ is removed.

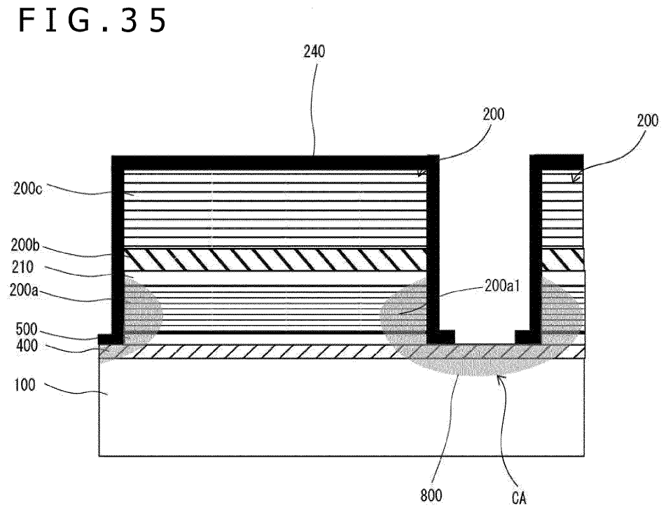

At the next Step S25, as depicted in FIG. 35, impurities are diffused from the contact area CA adjacent to the mesa structure 200, and the impurity area 800 is formed.

Specifically, impurities such as, for example, Zn are implanted and diffused from the contact area CA. For example, the impurity implantation rate and implantation time are adjusted such that the impurity area 800 is diffused to the contact layer 400, the substrate 100, the etching stop layer 500, and the side wall section 200a1 of the first multilayer film reflector 200a. At this time, the insulating film 240 functions as a mask at time of the impurity diffusion. For example, if SiO₂ is used as a material of the insulating film 240, vacancy diffusion is generated from Ga at a SiO₂ interface due to diffusion, depressurization, and heating, and it becomes easier to diffuse the impurities over a large area.

Note that because the impurities are diffused from the first multilayer film reflector 200a in the area 350 adjacent to the first mesa structure 150 after the first etching in the first example described above, there is a possibility that the impurities are diffused also to the to-be-selectively-oxidized layer 210.

In contrast to this, in the second example, etching is performed until the contact layer 400 is exposed, the second mesa structure 200 is formed, and then the impurities are diffused from the contact area CA. As a result, the possibility that the impurities are diffused to the to-be-selectively-oxidized layer 210 is low.

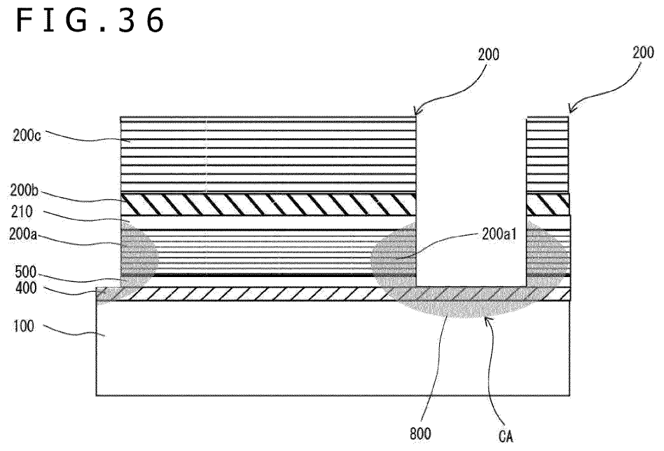

At the next Step S26, as depicted in FIG. 36, the remaining insulating film 240 is removed. Specifically, the insulating film 240 which is formed in areas other than the contact area CA is removed.

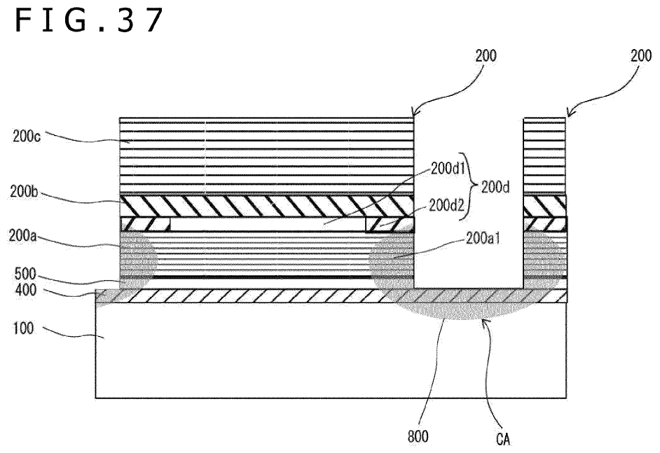

At the next Step S27, as depicted in FIG. 37, a peripheral section of the to-be-selectively-oxidized layer 210 (see FIG. 36) is oxidized, and the current constriction layer 200d is produced. Specifically, the mesa structure 200 is exposed to a water vapor atmosphere, the to-be-selectively-oxidized layer 210 is oxidized (selectively oxidized) from the side surface, and the current constriction layer 200d in which the periphery of the non-oxidized area 200d1 is surrounded by the oxidized area 200d2 is formed.

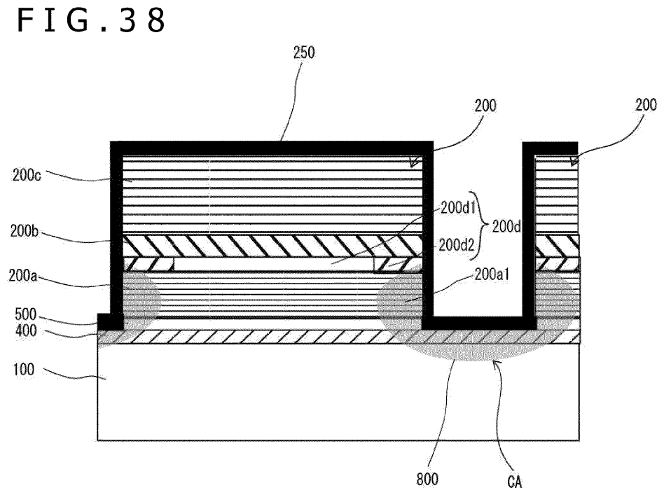

At the next Step S28, as depicted in FIG. 38, the insulating film 250 is formed on the mesa structure 200 and on the contact area CA adjacent to the mesa structure 200. Specifically, the insulating film 250 is formed in the substantially entire area of the stacked layer body 1000 where the mesa structure 200 is formed. Here, the contact area CA is located between two adjacent mesa structures 200 in the plan view.

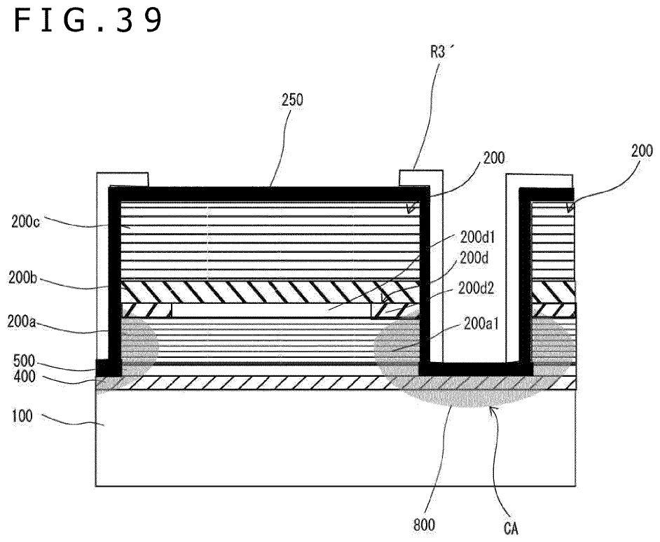

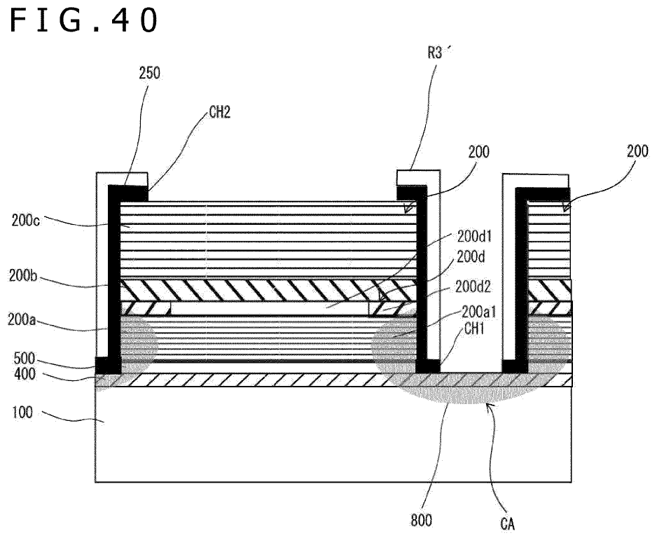

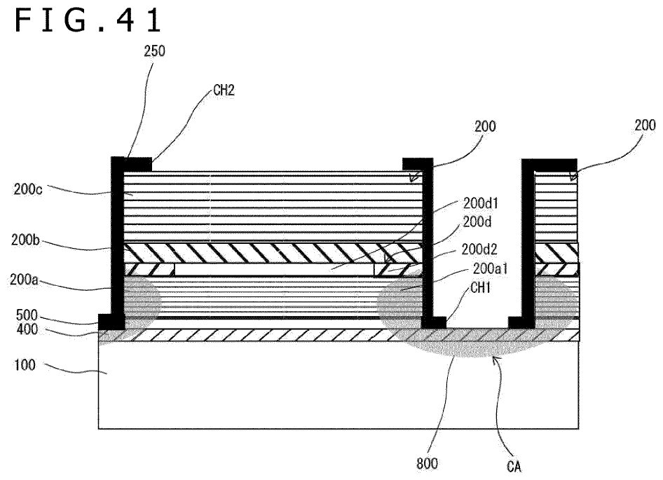

At the next Step S29, the insulating film 250 which is located on the mesa structure 200 and on the contact area CA adjacent to the mesa structure 200 is removed, and a contact hole is formed. Specifically, as depicted in FIG. 39, a resist pattern R3′ is formed by photolithography in areas other than the contact area CA adjacent to the mesa structure 200 and a top section of the mesa structure 200. Next, using the resist pattern R3′ as a mask, as depicted in FIG. 40, the insulating film 250 which is located on the contact area CA and the insulating film 250 which is located on the top section of the mesa structure 200 are removed by wet etching, and the contact holes CH1 and CH2 for electrode contact are formed. Thereafter, as depicted in FIG. 41, the resist pattern R3′ is removed.

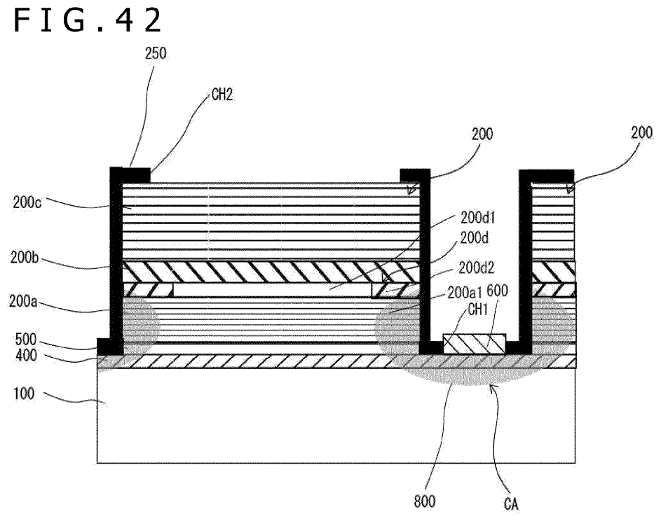

At the next Step S30, as depicted in FIG. 42, the anode electrode 600 is provided on the contact area CA adjacent to the mesa structure 200. Specifically, for example, by an EB vapor deposition method, an Au/Ti film is formed in the contact area CA, the resist and Au/Ti on the resist are lifted off, and thereby the anode electrode 600 is formed in the contact hole CH1.

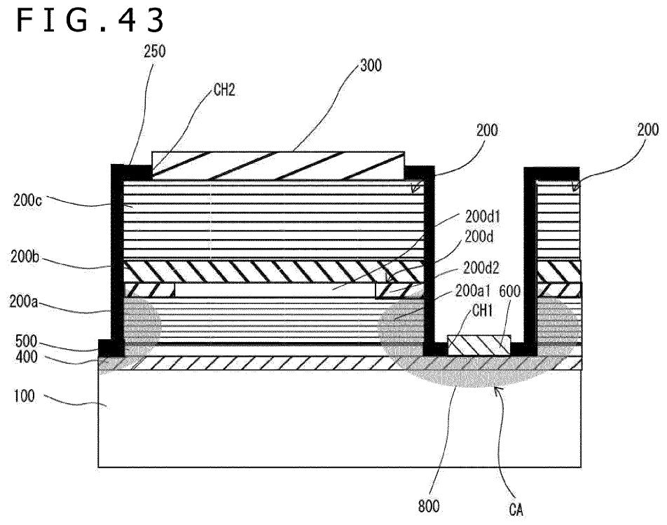

At the next Step S31, as depicted in FIG. 43, the cathode electrode 300 is provided on the top section of the mesa structure 200. Specifically, for example, by an EB vapor deposition method, an Au/Ti film is formed on the top section of the mesa structure 200, the resist and Au/Ti on the resist are lifted off, and thereby the cathode electrode 300 is formed in the contact hole CH2 on the top section of the mesa structure 200.

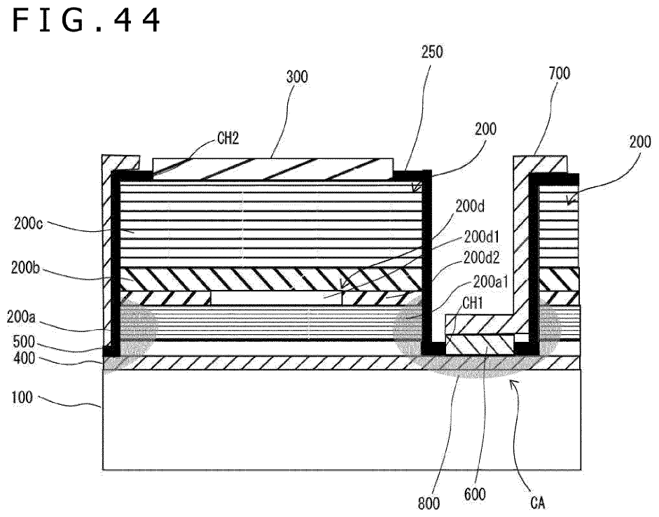

At the last Step S32, as depicted in FIG. 44, the metal wire 700 that connects the electrode pad and the anode electrode 600 provided in the contact area CA adjacent to the mesa structure 200 is formed. Thereafter, processes such as annealing, substrate film-thickness reduction by polishing the backside (the surface on a side opposite to the second-mesa-structure-200 side surface) of the substrate 100, or formation of an anti-reflection coating on the backside of the substrate 100 are performed, and a plurality of surface emission laser arrays on which a plurality of surface emission lasers 10 is arrayed two-dimensionally is formed on one wafer. Thereafter, the plurality of surface emission laser arrays is separated into a plurality of surface emission laser array chips by dicing.

Note that the order of Steps S30 and S31 described above may be reversed.

(3) Effects of Surface Emission Laser According to First Embodiment of Present Technology

In the surface emission laser 10, a current is injected into the contact area CA via the metal wire 700 and the anode electrode 600 from the electrode pad arranged around the surface emission laser array. The current injected into the contact area CA is injected into the active layer 200b through the low-resistance impurity area 800 and first multilayer film reflector 200a. Thereby, the active layer 200b emits light, and the light is emitted as laser light from the substrate-100 side when an oscillation condition is satisfied by being amplified while being repeatedly reflected between the first and second multilayer film reflectors 200a and 200c.

(4) Advantages of Surface Emission Laser According to First Embodiment of Present Technology

The surface emission laser 10 according to the first embodiment of the present technology includes the substrate 100 and the mesa structure 200 formed on the substrate 100. The mesa structure 200 includes the first multilayer film reflector 200a stacked on the substrate 100, the active layer 200b stacked on the first multilayer film reflector 200a, and the second multilayer film reflector 200c stacked on the active layer 200b. The impurity area 800 is provided over the contact area CA adjacent to the mesa structure 200 and contacting the anode electrode 600, and the side wall section 200a1 of a portion of the mesa structure 200 which portion includes the first multilayer film reflector 200a.

Thereby, a portion of a current path from the contact area CA to the active layer 200b which portion is located from the contact area CA to the side wall section 200a1 has a lower resistance, and so a current can be injected to the active layer 200b efficiently.

In this case, it is possible to inject the current to the active layer 200b efficiently even if the impurity concentration of the impurity area 800 is made relatively low.

As a result, according to the surface emission laser 10, it is possible to inject the current to the active layer 200b efficiently while suppressing deterioration of the crystallinity of layers stacked above the contact area CA.

On the other hand, for example, because impurities are doped at a high concentration in the contact area in the surface emission laser disclosed in PTL 1, the crystallinity of layers stacked above the contact area deteriorates. In addition, because the impurities are doped only in the contact area in the surface emission laser, there are many portions on a current path from the contact area to the active layer which portions do not have lowered resistances, and it is not possible to inject a current to the active layer efficiently.

The impurity area 800 is continuous from the contact area CA to the side wall section 200a1. Because the entire area between the contact area CA and the side wall section 200a1 has a lowered low resistance. Thereby, it is possible to inject a current to the active layer 200b more efficiently.

The mesa structure 200 includes the whole of the first multilayer film reflector 200a, and the contact area CA includes a part of the substrate 100.

The mesa structure 200 includes the whole of the first multilayer film reflector 200a, the surface emission laser 10 further includes the contact layer 400 arranged between the substrate 100 and the first multilayer film reflector 200a, and the contact area CA includes a part of the contact layer 400. Furthermore, the contact area includes a part of the substrate 100.

The thickness of the contact layer 400 is equal to or smaller than 1 μm. In this case, whereas the resistance of the contact layer 400 itself increases, optical absorption by the contact layer 400 can be reduced. Even if the resistance of the contact layer 400 itself increases, the low-resistance impurity area 800 reaches the contact layer 400, and so the resistance of the contact layer 400 in the current path substantially does not increase much or decreases.

The impurity concentration of the impurity area 800 is lower than 5×10¹⁹ cm⁻³. Thereby, deterioration of the crystallinity of layers (e.g. the first multilayer film reflector 200a, the active layer 200b, and the second multilayer film reflector 200c) stacked above the contact area CA can be suppressed more surely.

The cathode electrode 300 which is different from the anode electrode 600 contacts a surface of the mesa structure 200 which surface is located on the same side where the anode electrode 600 is arranged corresponding to the contact area CA. Thereby, for example, as compared with a case that both electrodes are arranged on opposite surfaces, a size increase of the surface emission laser 10 can be suppressed.

The substrate 100 is a semi-insulating substrate or a low-doped substrate. Thereby, optical absorption by the substrate 100 can be suppressed.

The surface emission laser 10 emits light toward a side of the substrate 100 which side is opposite to the mesa-structure-200 side. Thereby, for example, as compared with a surface emission laser that emits light from a top section of a mesa structure, the cathode electrode 300 with a larger size can be arranged, it is possible to cause a current to flow over a larger area of the mesa structure, and it is possible as a result to attempt to increase the optical output power.

An AlGaAs-based compound semiconductor is used in the surface emission laser 10.

The surface emission laser 10 further includes the current constriction layer 200d arranged between the first multilayer film reflector 200a and the second multilayer film reflector 200c. Because the current constriction layer 200d provides an effect of confining light and electrons in a small area, it is possible to attempt to reduce a threshold current of laser oscillation of the surface emission laser 10.

The first and second multilayer film reflectors 200a and 200c are both semiconductor multilayer reflectors. Thereby, it is possible to enhance the electrical conductivity of at least a current path from the contact area CA to the active layer 200b.

According to the surface emission laser array in which the surface emission laser 10 is arrayed two-dimensionally, it is possible to implement a high-efficiency and additionally low-power-consumption surface emission laser array.

The first example of the method of manufacturing the surface emission laser 10 includes a step of stacking at least the first multilayer film reflector 200a, the active layer 200b, and the second multilayer film reflector 200c on the substrate 100 in this order, and producing the stacked layer body 1000, a step of etching the stacked layer body 1000 until a part of the side surface of at least the first multilayer film reflector 200a is exposed, and forming the first mesa structure 150, a step of forming the insulating film 240 in the first mesa structure 150 and the area 350 adjacent to the first mesa structure 150, a step of removing the insulating film 240 formed in the adjacent area 350, a step of diffusing impurities from the adjacent area to the side wall section 200a1 of a portion of the first mesa structure 150 which portion includes the first multilayer film reflector 200a, a step of further etching the stacked layer body 1000 until another section of the side surface of the first multilayer film reflector 200a is exposed, and producing the second mesa structure 200 to replace the first mesa structure 150; and a step of providing the anode electrode 600 on an area adjacent to the second mesa structure 200.

In this case, because the impurities are implanted from the first multilayer film reflector 200a in the area 350 adjacent to the first mesa structure 150, it is possible to cause the impurities to permeate sufficiently to the side wall section 200a1 of the portion of the first multilayer film reflector 200a which portion is included in the first mesa structure 150.

In the first example, at the step of producing the stacked layer body 1000, the contact layer 400 is stacked on the substrate 100 before the first multilayer film reflector 200a is stacked on the substrate 100, and, at the step of forming the second mesa structure 200, the stacked layer body 1000 is etched until at least the contact layer 400 is exposed.

Thereby, the anode electrode 600 can be provided on the contact layer 400.

The second example of the method of manufacturing the surface emission laser 10 includes a step of stacking at least the first multilayer film reflector 200a, the active layer 200b, and the second multilayer film reflector 200c on the substrate 100 in this order, and producing the stacked layer body 1000, a step of etching the stacked layer body 1000 until at least a part of the side surface of at least the first multilayer film reflector 200a is exposed, and forming the mesa structure 200; a step of forming the insulating film 240 in the mesa structure 200 and the area 350 adjacent to the mesa structure 200, a step of removing the insulating film 240 formed in the adjacent area 350, a step of diffusing impurities from the adjacent area 350 to the side wall section 200a1 of a portion of the mesa structure 200 which portion includes the first multilayer film reflector 200a, and a step of providing the anode electrode 600 on the adjacent area 350.

In this case, the mesa structure 200 can be formed by performing etching once, and so the man-hours can be reduced.

In addition, because the impurities are implanted from the contact area CA adjacent to the mesa structure 200, diffusion of the impurities to the to-be-selectively-oxidized layer 210 can be suppressed.

In the second example, at the step of producing the stacked layer body 1000, the contact layer 400 is stacked on the substrate 100 before the first multilayer film reflector 200a is stacked on the substrate 100, and, at the step of forming the mesa structure 200, the stacked layer body 1000 is etched until the contact layer 400 is exposed.

Thereby, the anode electrode 600 can be provided on the contact layer 400.

2. <Surface Emission Laser According to Second Embodiment of Present Technology>

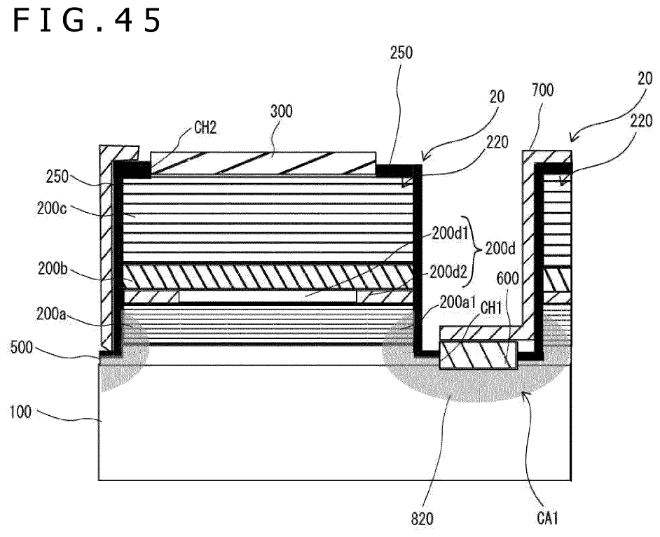

As depicted in FIG. 45, a surface emission laser 20 according to a second embodiment has configuration similar to the configuration of the surface emission laser 10 according to the first embodiment except that the surface emission laser 20 does not have the contact layer 400.

That is, in the surface emission laser 20 also, a mesa structure 220 includes the whole of the first multilayer film reflector 200a, and a contact area CA1 includes a part of the substrate 100. Here, the contact area CA1 also includes a part of the etching stop layer 500.

In the surface emission laser 20, the top surface (the bottom surface of the contact hole CH1) of the contact area CA1 (here, located between two adjacent mesa structures 20 in the plan view) adjacent to the mesa structure 220 is positioned in the substrate 100.

In the surface emission laser 20, an impurity area 820 includes a part of the substrate 100, a part of the etching stop layer 500, and the side wall section 200a1 of the first multilayer film reflector 200a.

The surface emission laser 20 also can be manufactured by a manufacturing method corresponding to the first and second examples of the method of manufacturing the surface emission laser 10 (however, the step of stacking the contact layer 400 is excluded).

According to the surface emission laser 20 according to the second embodiment, advantages similar to the advantages of the surface emission laser 10 can be attained, and also the man-hours at time of manufacturing can be reduced by an amount corresponding to the omission of stacking of the contact layer 400.

3. <Surface Emission Laser According to Third Embodiment of Present Technology>

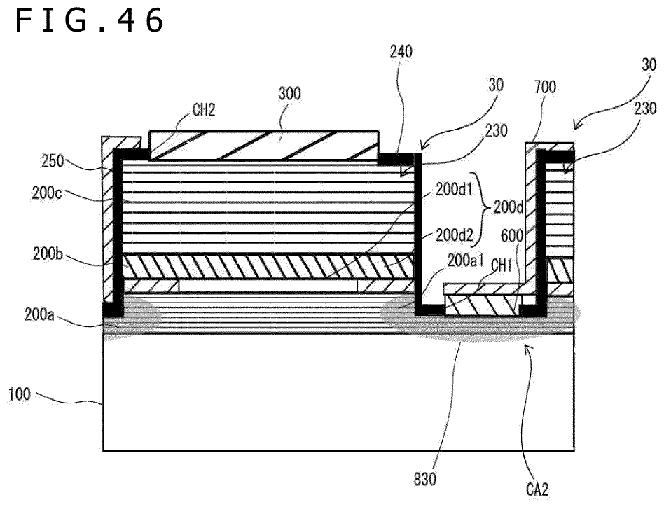

Unlike the surface emission laser 10 according to the first embodiment, as depicted in FIG. 46, a surface emission laser 30 according to the third embodiment does not have the contact layer 400 and the etching stop layer 500.

Furthermore, in the surface emission laser 30, a mesa structure 230 includes portions other than a bottom section (lower section) of the first multilayer film reflector 200a (includes a top section of the first multilayer film reflector 200a), and a contact area CA2 includes a part of the bottom section of the first multilayer film reflector 200a. The mesa structure 230 is substantially identical to the first mesa structure 150 explained in the first example of the method of manufacturing the surface emission laser 10.

That is, in the surface emission laser 30, the top surface (the bottom surface of the contact hole CH1) of the contact area CA2 (here, located between two adjacent mesa structures 230 in the plan view) adjacent to the mesa structure 230 is positioned in the first multilayer film reflector 200a. Here, the contact area CA2 includes a part of the substrate 100 and a part of a lower section of the first multilayer film reflector 200a. Note that the contact area CA2 may not include a part of the substrate 100.

According to the surface emission laser 20, advantages similar to the advantages of the surface emission laser 10 can be attained, and also the man-hours at time of manufacturing can be reduced more than in the second embodiment described above by an amount corresponding to the omission of stacking of the contact layer 400 and the etching stop layer 500.

In the surface emission laser 30, an impurity area 830 includes a lower section and side wall section 200a1 of the first multilayer film reflector 200a, and a part of the substrate 100.

The surface emission laser 30 can be manufactured by a method equivalent to the first example of the method of manufacturing the surface emission laser 10 mentioned above (however, the area 350 adjacent to the first mesa structure 150 functions as the contact area CA2).

4. <Modification Examples of Surface Emission Laser According to Present Technology>

The present technology is not limited to each embodiment described above, but various modifications are possible.

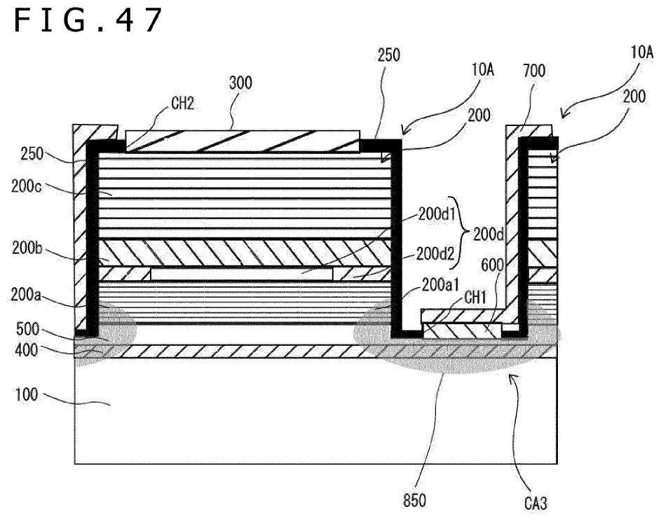

For example, in a surface emission laser 10A according to a first modification example of the first embodiment depicted in FIG. 47, the bottom surface (etching bottom surface) of the contact hole CH1 which is the top surface of a contact area CA3 is positioned in the etching stop layer 500.

In the first modification example, an impurity area 850 includes a part of the etching stop layer 500, a part of the contact layer 400, a part of the substrate 100, and the side wall section 200a1 of the first multilayer film reflector 200a.

In the surface emission laser 10A also, because it is attempted to lower the resistance of a current path from the contact area CA3 to the side wall section 200a1 by forming the impurity area 850, it is possible to cause a current to flow from the anode electrode 600 to the active layer 200b efficiently.

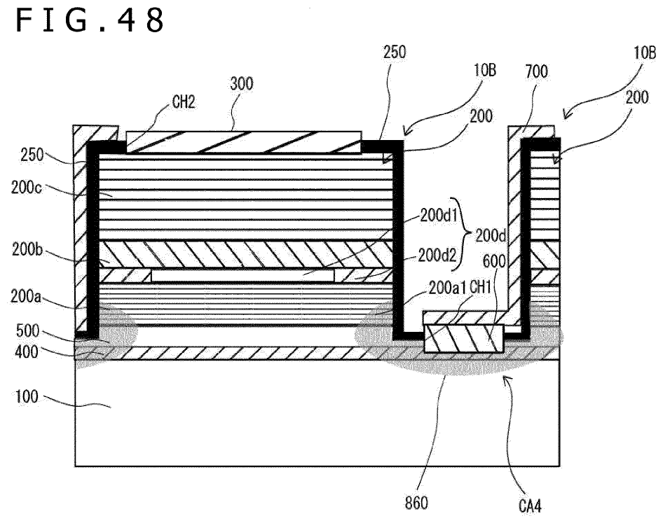

For example, in a surface emission laser 10B according to a second modification example of the first embodiment depicted in FIG. 48, the bottom surface (etching bottom surface) of the contact hole CH1 which is the top surface of a contact area CA4 is positioned in the contact layer 400.

In the second modification example, an impurity area 860 includes a part of the etching stop layer 500, a part of the contact layer 400, a part of the substrate 100, and the side wall section 200a1 of the first multilayer film reflector 200a.

In the surface emission laser 10B also, because it is attempted to lower the resistance of a current path from the contact area CA4 to the side wall section 200a1 by forming the impurity area 860, it is possible to cause a current to flow from the anode electrode 600 to the active layer 200b efficiently.

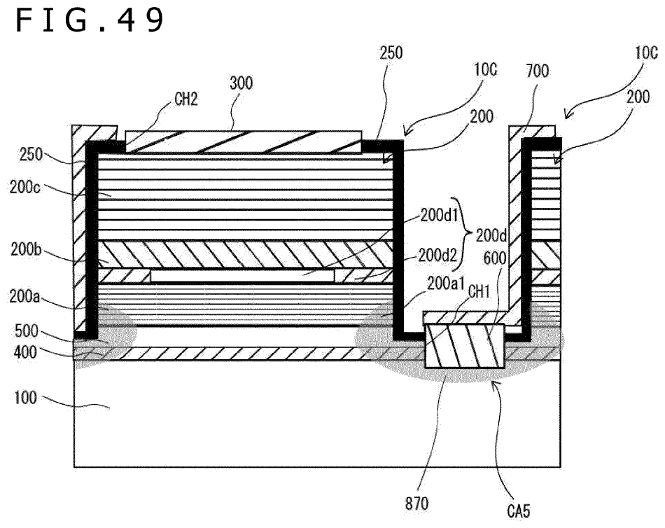

For example, in a surface emission laser 10C according to a third modification example of the first embodiment depicted in FIG. 49, the bottom surface (etching bottom surface) of the contact hole CH1 which is the top surface of a contact area CA5 is positioned in the substrate 100.

In the third modification example, an impurity area 870 includes a part of the etching stop layer 500, a part of the contact layer 400, a part of the substrate 100, and the side wall section 200a1 of the first multilayer film reflector 200a.

In the surface emission laser 10C also, because it is attempted to lower the resistance of a current path from the contact area CA5 to the side wall section 200a1 by forming the impurity area 870, it is possible to cause a current to flow from the anode electrode 600 to the active layer 200b efficiently.

Whereas both the first and second multilayer film reflectors 200a and 200c are semiconductor multilayer film reflectors in each embodiment and each modification example described above, this is not the sole example.

For example, the first multilayer film reflector 200a may be a semiconductor multilayer film reflector, and additionally the second multilayer film reflector 200c may be a dielectric multilayer film reflector. A dielectric multilayer film reflector also is a type of distributed Bragg reflector.

For example, the first multilayer film reflector 200a may be a dielectric multilayer film reflector, and additionally the second multilayer film reflector 200c may be a semiconductor multilayer film reflector.

For example, both the first and second multilayer film reflectors 200a and 200b may be dielectric multilayer film reflectors.

Semiconductor multilayer film reflectors have low optical absorbance and additionally have electrical conductivity. From this perspective, a semiconductor multilayer film reflector is suitable for the first multilayer film reflector 200a which is located on the emission side (backside), and additionally on a current path from the anode electrode 600 to the active layer 200b.

On the other hand, dielectric multilayer film reflectors have extremely low optical absorbance. From this perspective, a dielectric multilayer film reflector is suitable for the first multilayer film reflector 200 which is located on the emission side (backside).

Whereas a backside-emission surface emission laser that emits laser light from the substrate side is explained as an example in each embodiment and each modification example described above, the present technology can also be applied to a frontside-emission surface emission laser that emits laser light from the mesa-structure side.

In this case, for example, preferably an emission port is formed inside the electrode provided on the top section of the mesa structure by forming the electrode as an annular or frame-shaped electrode or the electrode provided on the top section of the mesa structure is formed as an electrode transparent to an oscillation wavelength.

Whereas the surface emission laser 10 that uses an AlGaAs-based compound semiconductor is explained as an example in each embodiment and each modification example described above, the present technology can also be applied to a surface emission laser that uses a GaN-based compound semiconductor, for example.

Specifically, a GaN-based semiconductor multilayer film reflector may be used for at least one of the first and second multilayer film reflectors 200a and 200b or a GaN-based dielectric multilayer film reflector may be used for at least one of the first and second multilayer film reflectors 200a and 200b.

Examples of the GaN-based compound semiconductor used for at least one of the first and second multilayer film reflectors 200a and 200b include, for example, GaN/AlGaN and the like.

Whereas a surface emission laser array in which the surface emission laser 10 is arrayed two-dimensionally is explained as an example in each embodiment and each modification example described above, this is not the sole example. The present technology can also be applied to a surface emission laser array in which the surface emission laser 10 is arrayed one-dimensionally, a single surface emission laser 10, and the like.

5. <Use Examples of Surface Emission Laser to which Present Technology is Applied>

The surface emission laser according to each embodiment described above and each modification example described above of the present technology can be applied to electronic equipment that emits laser light such as a TOF (Time Of Flight) sensor, for example. In a case where the surface emission laser is applied to a TOF sensor, for example, such a TOF sensor can be a distance image sensor that uses a direct TOF measurement method or a distance image sensor that uses an indirect TOF measurement method. Because a distance image sensor that uses a direct TOF measurement method determines an arrival timing of photon directly in the time domain in each pixel, it transmits, from a light source, light pulses with short pulse widths, and produces electrical pulses at light receiving elements. The present disclosure can be applied to the light source used at that time. In addition, in an indirect TOF method, a semiconductor element structure whose detection and storage amount of a carrier generated by light change depending on the arrival timing of light is used to measure the flight time of light. The present disclosure can also be applied as a light source in a case where such an indirect TFO method is used.

The surface emission laser according to the present technology may be implemented as light sources of the TOF sensors described above mounted on a mobile body of any type such as a car, an electric car, a hybrid electric car, a motorcycle, a bicycle, a personal mobility, an airplane, a drone, a ship, or a robot.

The surface emission laser according to the present technology may be implemented as a light source of equipment that forms or displays images by laser light (e.g. a laser printer, a laser copying machine, a projector, a head-mount display, a head-up display, etc.).

In addition, the present technology can also have configuration like the ones mentioned below.

(1)

The present technology is a surface emission laser including:

a substrate; and

a mesa structure formed on the substrate, in which

the mesa structure includes
at least a part of a first multilayer film reflector stacked on the substrate,
an active layer stacked on the first multilayer film reflector, and
a second multilayer film reflector stacked on the active layer, and

an impurity area is provided over a contact area that is adjacent to the mesa structure and contacts an electrode, and over a side wall section of a portion of the mesa structure that the portion includes the first multilayer film reflector.

(2)

The surface emission laser according to (1), in which the impurity area is continuous from the contact area to the side wall section.

(3)

The surface emission laser according to (1) or (2), in which

the mesa structure includes the whole of the first multilayer film reflector, and the contact area includes a part of the substrate.

(4)

The surface emission laser according to (1) or (2), in which

the mesa structure includes a portion other than a bottom section of the first multilayer film reflector, and

the contact area includes a part of the bottom section of the first multilayer film reflector.

(5)

The surface emission laser according to (1) or (2), in which

the mesa structure includes the whole of the first multilayer film reflector,

the surface emission laser further includes a contact layer arranged between the substrate and the first multilayer film reflector, and

the contact area includes a part of the contact layer.

(6)

The surface emission laser according to claim (5), in which the contact area includes a part of the substrate.

(7)

The surface emission laser according to (5) or (6), in which a thickness of the contact layer is equal to or smaller than 1 μm.

(8)

The surface emission laser according to any one of (1) to (7), in which an impurity concentration of the impurity area is lower than 5×10¹⁹ cm⁻³.

(9)

The surface emission laser according to any one of (1) to (8), in which other electrodes contact a surface of the mesa structure that the surface is located on a same side where the electrode is arranged corresponding to the contact area.

(10)

The surface emission laser according to any one of (1) to (9), in which the substrate is a semi-insulating substrate or a low-doped substrate.

(11)

The surface emission laser according to any one of (1) to (10), in which the surface emission laser emits light toward a side of the substrate that the side is opposite to a mesa-structure side.

(12)

The surface emission laser according to any one of (1) to (11), in which an AlGaAs-based compound semiconductor or a GaN-based compound semiconductor is used in the surface emission laser.

(13)

The surface emission laser according to any one of (1) to (12), further including a current constriction layer arranged between the first multilayer film reflector and the second multilayer film reflector.

(14)

The surface emission laser according to any one of (1) to (13), in which at least one of the first and second multilayer film reflectors is a semiconductor multilayer reflector.

(15)

The surface emission laser according to any one of (1) to (13), in which at least one of the first and second multilayer film reflectors is a dielectric multilayer film reflector.

(16)

A surface emission laser array, in which the surface emission laser according to any one of (1) to (15) is arrayed two-dimensionally.

(17)

Electronic equipment including the surface emission laser array according to (16).

(18)

A surface emission laser manufacturing method including:

a step of stacking at least a first multilayer film reflector, an active layer, and a second multilayer film reflector on a substrate in this order, and producing a stacked layer body;

a step of etching the stacked layer body until a part of a side surface of at least the first multilayer film reflector is exposed, and forming a first mesa structure;

a step of forming an insulating film in the first mesa structure and an area adjacent to the first mesa structure;

a step of removing the insulating film formed in the adjacent area;

a step of diffusing impurities from the adjacent area to a side wall section of a portion of the first mesa structure that the portion includes the first multilayer film reflector;

a step of further etching the stacked layer body until another section of the side surface of at least the first multilayer film reflector is exposed, and forming and producing a second mesa structure to replace the first mesa structure; and a step of providing an electrode on an area adjacent to the second mesa structure.

(19)

The surface emission laser manufacturing method according to (18), in which

at the step of producing the stacked layer body, a contact layer is stacked on the substrate before the first multilayer film reflector is stacked on the substrate, and

at the step of forming the second mesa structure, the stacked layer body in which the first mesa structure is formed is etched until at least the contact layer is exposed.

(20)

A surface emission laser manufacturing method including:

a step of stacking at least a first multilayer film reflector, an active layer, and a second multilayer film reflector on a substrate in this order, and producing a stacked layer body;

a step of etching the stacked layer body until at least a part of a side surface of at least the first multilayer film reflector is exposed, and forming a mesa structure;

a step of forming an insulating film in the mesa structure and an area adjacent to the mesa structure;

a step of removing the insulating film formed in the adjacent area;

a step of diffusing impurities from the adjacent area to a side wall section of a portion of the mesa structure that the portion includes the first multilayer film reflector; and a step of providing an electrode on the adjacent area.

(21)

The surface emission laser manufacturing method according to (20), in which

at the step of producing the stacked layer body, a contact layer is stacked on the substrate before the first multilayer film reflector is stacked on the substrate, and at the step of forming the mesa structure, the stacked layer body is etched until at least the contact layer is exposed.

### REFERENCE SIGNS LIST

10: Surface emission laser
100: Substrate
150: First mesa structure
200: Second mesa structure (mesa structure)
200a: First multilayer film reflector
200b: Active layer
200c: Second multilayer film reflector
200d: Current constriction layer
400: Contact layer
600: Anode electrode (electrode)
800: Impurity area
1000: Stacked layer body
CA, CA1, CA2, CA3, CA4, CA5: Contact area

1. A surface emission laser comprising:
a substrate; and
a mesa structure formed on the substrate, wherein
the mesa structure includes
at least a part of a first multilayer film reflector stacked on the substrate,
an active layer stacked on the first multilayer film reflector, and
a second multilayer film reflector stacked on the active layer, and
an impurity area is provided over a contact area that is adjacent to the mesa structure and contacts an electrode, and over a side wall section of a portion of the mesa structure that the portion includes the first multilayer film reflector.

2. The surface emission laser according to claim 1, wherein the impurity area is continuous from the contact area to the side wall section.

3. The surface emission laser according to claim 1, wherein
the mesa structure includes the whole of the first multilayer film reflector, and
the contact area includes a part of the substrate.

4. The surface emission laser according to claim 1, wherein
the mesa structure includes a portion other than a bottom section of the first multilayer film reflector, and
the contact area includes a part of the bottom section of the first multilayer film reflector.

5. The surface emission laser according to claim 1, wherein
the mesa structure includes the whole of the first multilayer film reflector,
the surface emission laser further includes a contact layer arranged between the substrate and the first multilayer film reflector, and
the contact area includes a part of the contact layer.

6. The surface emission laser according to claim 5, wherein the contact area includes a part of the substrate.

7. The surface emission laser according to claim 5, wherein a thickness of the contact layer is equal to or smaller than 1 μm.

8. The surface emission laser according to claim 1, wherein an impurity concentration of the impurity area is lower than 5×10¹⁹ cm⁻³.

9. The surface emission laser according to claim 1, wherein other electrodes contact a surface of the mesa structure that the surface is located on a same side where the electrode is arranged corresponding to the contact area.

10. The surface emission laser according to claim 1, wherein the substrate is a semi-insulating substrate or a low-doped substrate.

11. The surface emission laser according to claim 1, wherein light is emitted toward a side of the substrate that the side is opposite to a mesa-structure side.

12. The surface emission laser according to claim 1, wherein an AlGaAs-based compound semiconductor or a GaN-based compound semiconductor is used.

13. The surface emission laser according to claim 1, further comprising:
a current constriction layer arranged between the first multilayer film reflector and the second multilayer film reflector.

14. The surface emission laser according to claim 1, wherein at least one of the first and second multilayer film reflectors is a semiconductor multilayer film reflector.

15. The surface emission laser according to claim 1, wherein at least one of the first and second multilayer film reflectors is a dielectric multilayer film reflector.

16. A surface emission laser array, wherein the surface emission laser according to claim 1 is arrayed two-dimensionally.

17. Electronic equipment comprising:
the surface emission laser array according to claim 16.

18. A surface emission laser manufacturing method comprising:
a step of stacking at least a first multilayer film reflector, an active layer, and a second multilayer film reflector on a substrate in this order, and producing a stacked layer body;
a step of etching the stacked layer body until a part of a side surface of at least the first multilayer film reflector is exposed, and forming a first mesa structure;
a step of forming an insulating film in the first mesa structure and an area adjacent to the first mesa structure;
a step of removing the insulating film formed in the adjacent area;
a step of diffusing impurities from the adjacent area to a side wall section of a portion of the first mesa structure that the portion includes the first multilayer film reflector;
a step of further etching the stacked layer body until another section of the side surface of at least the first multilayer film reflector is exposed, and forming a second mesa structure to replace the first mesa structure; and
a step of providing an electrode on an area adjacent to the second mesa structure.

19. The surface emission laser manufacturing method according to claim 18, wherein
at the step of producing the stacked layer body, a contact layer is stacked on the substrate before the first multilayer film reflector is stacked on the substrate, and
at the step of forming the second mesa structure, the stacked layer body in which the first mesa structure is formed is etched until at least the contact layer is exposed.

20. A surface emission laser manufacturing method comprising:
a step of stacking at least a first multilayer film reflector, an active layer, and a second multilayer film reflector on a substrate in this order, and producing a stacked layer body;
a step of etching the stacked layer body until at least a part of a side surface of at least the first multilayer film reflector is exposed, and forming a mesa structure;
a step of forming an insulating film in the mesa structure and an area adjacent to the mesa structure;
a step of removing the insulating film formed in the adjacent area;
a step of diffusing impurities from the adjacent area to a side wall section of a portion of the mesa structure that the portion includes the first multilayer film reflector; and
a step of providing an electrode on the adjacent area.

21. The surface emission laser manufacturing method according to claim 20, wherein
at the step of producing the stacked layer body, a contact layer is stacked on the substrate before the first multilayer film reflector is stacked on the substrate, and
at the step of forming the mesa structure, the stacked layer body is etched until at least the contact layer is exposed.
